(19) United States
(12) Patent Application Publication
(10) Pub. No.: US 2005/0126605 A1
(43) Pub. Date: Jun. 16, 2005

(54) Apparatus and method for cleaning surfaces

(75) Inventors: Yuval Yassour, Kibbutz Hasolelim (IL); Hilel Richman, Haifa (IL)

Correspondence Address: SQUIRE, SANDERS & DEMPSEY L.L.P, 600 HANSEN WAY, PALO ALTO, CA, 94304-1043, US

(73) Assignee: COREFLOW SCIENTIFIC SOLUTIONS LTD., Yoqneam (IL)

(21) Appl. No.: 10/736,880

(22) Filed: Dec. 15, 2003

(51) Int. Cl. B08B 3/00

(52) U.S. Cl. 134/34; 134/172; 134/198

(57) ABSTRACT

A cleaning device for removing contaminants from a surface of an object to be cleaned, the device adapted to be fluidically connected to a high-pressure gas supply. The device comprises at least one high-pressure passage with a predetermined miniature lateral scale with a high-pressure outlet for accelerating the gas. The high-pressure outlet characterized by at least one narrow lip, where the outlet and the narrow lip defining an active surface. When the active surface of the cleaning device is brought to a predetermined miniature gap from, and substantially parallel to, the surface, thus defining a throat section between the narrow lip and the surface of the object to be cleaned and the gas accelerated to about sonic speeds at the throat section, lateral aeromechanic removal forces are produced that act on the contaminants.

### FIELD OF THE INVENTION

The present invention relates to a cleaning apparatus and method for removing contaminating particles off surfaces. In particular, the present invention relates to a cleaning method and apparatus employing aerodynamic principles, especially suitable for cleaning planar and smooth substrates such as silicon Wafers and similar semiconductors products, Flat Panel Displays (FPD), (masks for SC/FPD), Liquid Crystal Display (LCD) panels, Printed Circles Boards (PCB) and glass or optical surfaces, as well as media such as hard disks, CD & DVD, cardboards, and surfaces of optical lenses and devices, metallic and plastic surfaces, celluloid and film sheets, and various flat media and surfaces that are highly susceptible to contaminating particles.

### BACKGROUND OF THE INVENTION

Many industrial fields relate to clean flat or non-flat, essentially smooth surfaces. In particular, production lines as well as research and development sites in the semiconductors industry must be kept under extremely clean conditions. It is true also in the FPD, CD, DVD, LCD industry and in other similar production lines. In such industries, the process of manufacturing is highly sensitive to contaminating particles. Therefore, production is usually conducted in clean rooms of different classes, where the ambient air is constantly filtered to trap miniature airborne contaminating particles (including particles of sub-micron proportions). However, there are still contamination problems in clean rooms, mostly introduced by the manufacturing process itself and by the handling tools such as standard wafer grippers (for-example, end-effectors and vacuum chucks), that are commonly used in the semiconductor industry as well as in the FPD industry.

Particularly, in the semiconductors industry, it is important to remove miniature contaminating particles from both sides of the wafer. The presence of a particle in the magnitude order of only 0.1 micrometer (μm) contaminating the wafer front-side, can result in microelectronic failures. Furthermore, when the wafer undergoes a process of photolithography, the surface of the wafer has to be completely flat. The wafer is commonly held down in contact with a flat vacuum chuck, and if any particles, even of minute dimensions (in the order of 0.5 μm and more), exist on the wafer backside, it may result with local wafer deformation that can render the photolithography process unsuccessful. In addition, contaminating particles at the backside of an upper wafer may drop to the front-side of a lower wafer when both are stored one over the other in a standard wafer cassette.

Apart from the semiconductor industry, the manufacturing process of flat panel displays (FPD), liquid crystal displays (LCD), printed circuit boards (PCB), as well as the Hard-disks, DVD and CD, and many more products, is very sensitive to contaminating particles, which may cause a significant reduction of production yield.

Wafers and FPDs production lines, incorporate many cleaning stations that are mostly based on wet cleaning methods. In large scale industries cleaning stations based on dry cleaning methods are trendy.

As indicated, manufacturing processes that take place in clean rooms, mainly in the semiconductors and the FPD industries, are still susceptible to small-size contaminating particles. Therefore, in-line cleaning stations are extensively used. Such a cleaning stations must clean the substrate but must not add new contaminating particles when handling or chucking, in order to meet quality control specifications, the latter becoming increasingly demanding each year. It is relevant with respect to chucks that hold the wafers during the cleaning process and to the handling tools that unload the wafer after cleaning. Moreover, in many cases it is imperatively forbidden to touch the surfaces. For example, it is forbidden to touch the front side of a wafer when cleaning its back-side, since touching may introduce contaminating particles and contact may directly damage microelectronic patterns. Therefore a dry cleaning apparatus that supports the object by non-contact means during the cleaning process may be of great added value.

### SUMMARY OF THE INVENTION

There is thus provided, in accordance with a preferred embodiment of the present invention, a method for removing contaminants from a surface of an object to be cleaned, the method comprising:
providing a cleaning device fluidically connected to a high-pressure gas supply, the device comprising at least one high-pressure passage of a predetermined miniature lateral scale with a high-pressure outlet for accelerating the gas, the high-pressure outlet characterized by at least one narrow lip, the outlet and the narrow lip defining an active surface;
bringing the active surface of the cleaning device to a predetermined miniature gap from, and substantially parallel to, the surface of the object to be cleaned, thus defining a throat section associated with the device between said at least one narrow lip and the surface of the object to be cleaned, wherein the gap is the width of the throat section;
accelerating the gas to about sonic speeds at the throat section;
thereby producing lateral aeromechanic removal forces that act on the contaminants.

Furthermore, in accordance with a preferred embodiment of the present invention, the width of the throat section is reduced below a predetermined distance to attain a high gradient of velocity of the gas, thereby controlling mass flow.

Furthermore, in accordance with a preferred embodiment of the present invention, the width of the throat section is regulated.

Furthermore, in accordance with a preferred embodiment of the present invention, the width of the throat section is in the order of 100 to 1000 microns.

Furthermore, in accordance with a preferred embodiment of the present invention, the width of the throat section is about 30 to 100 microns.

Furthermore, in accordance with a preferred embodiment of the present invention, the width of the throat section is about 30 microns or less.

Furthermore, in accordance with a preferred embodiment of the present invention, the narrow lip is sharp.

Furthermore, in accordance with a preferred embodiment of the present invention, the lateral scale of the high-pressure passage is about the same in size as the width of the throat section.

Furthermore, in accordance with a preferred embodiment of the present invention, the lateral scale of the high-pressure passage is significantly larger than the width of the throat section.

Furthermore, in accordance with a preferred embodiment of the present invention, the lateral scale of the high-pressure passage is significantly smaller than the width of the throat section.

Furthermore, in accordance with a preferred embodiment of the present invention, pressure of the high-pressure gas supply is regulated.

Furthermore, in accordance with a preferred embodiment of the present invention, pressure of the high-pressure gas supply is up to 5 bars.

Furthermore, in accordance with a preferred embodiment of the present invention, pressure of the high-pressure gas supply is up to 20 bars.

Furthermore, in accordance with a preferred embodiment of the present invention, pressure of the high-pressure gas supply is up to 100 bars.

Furthermore, in accordance with a preferred embodiment of the present invention, the method further comprises evacuating the gas through at least one gas evacuation passage, confining said at least one high-pressure outlet within, and having external rims, provided in the device.

Furthermore, in accordance with a preferred embodiment of the present invention, evacuating the gas through at least one gas evacuation passage is carried out by vacuum means.

Furthermore, in accordance with a preferred embodiment of the present invention, the vacuum means and the high-pressure gas supply are both regulated to induce substantially zero pressure forces on the object to be cleaned.

Furthermore, in accordance with a preferred embodiment of the present invention, the vacuum means evacuate substantially all the gas so that in effect a dynamically closed environment is formed substantially preventing mass flow of the gas with removed contaminants from escaping to ambient atmosphere.

Furthermore, in accordance with a preferred embodiment of the present invention, comprising providing a relative motion between the active surface of the device and the surface of the object to be cleaned.

Furthermore, in accordance with a preferred embodiment of the present invention, the relative motion is linear.

Furthermore, in accordance with a preferred embodiment of the present invention, the relative motion is angular.

Furthermore, in accordance with a preferred embodiment of the present invention, the relative motion is combined with linear motion.

Furthermore, in accordance with a preferred embodiment of the present invention, the relative motion is substantially parallel to the surface and the direction of the gas as it accelerates in the throat section.

Furthermore, in accordance with a preferred embodiment of the present invention, the active surface of the device is occasionally relocated from point to point to clean localized portions of the surface to be cleaned.

Furthermore, in accordance with a preferred embodiment of the present invention, the width of the throat section is controlled using physical support.

Furthermore, in accordance with a preferred embodiment of the present invention, the width of the throat section is controlled using non-contact support.

Furthermore, in accordance with a preferred embodiment of the present invention, the non-contact support comprises air-cushioning.

Furthermore, in accordance with a preferred embodiment of the present invention, the gas is air.

Furthermore, in accordance with a preferred embodiment of the present invention, the gas is helium.

Furthermore, in accordance with a preferred embodiment of the present invention, the gas is Nitrogen.

Furthermore, in accordance with a preferred embodiment of the present invention, the gas is heated.

Furthermore, in accordance with a preferred embodiment of the present invention, the surface to be cleaned is heated.

Furthermore, in accordance with a preferred embodiment of the present invention, the gas is excited in high-frequency a periodic fluctuations.

Furthermore, in accordance with a preferred embodiment of the present invention, the gas is excited by piezoelectrically.

Furthermore, in accordance with a preferred embodiment of the present invention, the gas is excited by acoustically.

Furthermore, in accordance with a preferred embodiment of the present invention, there is provided a cleaning device for removing contaminants from a surface of an object to be cleaned, the device adapted to be fluidically connected to a high-pressure gas supply, the device comprising:
at least one high-pressure passage with a predetermined miniature lateral scale with a high-pressure outlet for accelerating the gas, the high-pressure outlet characterized by at least one narrow lip, the outlet and the narrow lip defining an active surface,
whereby when the active surface of the cleaning device is brought to a predetermined miniature gap from, and substantially parallel to, the surface, thus defining a throat section between said at least one narrow lip and the surface of the object to be cleaned, wherein the gap is the width of the throat section, and when the gas is accelerated to about sonic speeds at the throat section, lateral aeromechanic removal forces are produced that act on the contaminants.

Furthermore, in accordance with a preferred embodiment of the present invention, the width of the throat section is controlled by a mechanical means.

Furthermore, in accordance with a preferred embodiment of the present invention, the width of the throat section is controlled by an aeromechanical means.

Furthermore, in accordance with a preferred embodiment of the present invention, the width of the throat section is set to be in the order of 100 to 1000 microns.

Furthermore, in accordance with a preferred embodiment of the present invention, the width of the throat section is set to be about 30 to 100 microns.

Furthermore, in accordance with a preferred embodiment of the present invention, the width of the throat section is set to be about 30 microns or less.

Furthermore, in accordance with a preferred embodiment of the present invention, the narrow lip is sharp.

Furthermore, in accordance with a preferred embodiment of the present invention, the lateral scale of the high-pressure passage is about the same in size as the width of the throat section.

Furthermore, in accordance with a preferred embodiment of the present invention, the lateral scale of the high-pressure passage is significantly larger than the width of the throat section.

Furthermore, in accordance with a preferred embodiment of the present invention, the lateral scale of the high-pressure passage is significantly smaller than the width of the throat section.

Furthermore, in accordance with a preferred embodiment of the present invention, pressure of the high-pressure gas supply is regulated.

Furthermore, in accordance with a preferred embodiment of the present invention, pressure of the high-pressure gas supply is up to 5 bars.

Furthermore, in accordance with a preferred embodiment of the present invention, pressure of the high-pressure gas supply is up to 20 bars.

Furthermore, in accordance with a preferred embodiment of the present invention, pressure of the high-pressure gas supply is up to 100 bars.

Furthermore, in accordance with a preferred embodiment of the present invention, the device further comprises at least one gas evacuation passage.

Furthermore, in accordance with a preferred embodiment of the present invention, said at least one gas evacuating passage is connected to a vacuum pump.

Furthermore, in accordance with a preferred embodiment of the present invention, the device further comprises a relative motion means, for providing relative motion between the active surface of the device and the surface to be cleaned.

Furthermore, in accordance with a preferred embodiment of the present invention, the relative motion means provides linear motion.

Furthermore, in accordance with a preferred embodiment of the present invention, the relative motion means provides angular motion.

Furthermore, in accordance with a preferred embodiment of the present invention, the relative motion means facilitates motion combined with linear motion.

Furthermore, in accordance with a preferred embodiment of the present invention, the relative motion is provided by mechanical means.

Furthermore, in accordance with a preferred embodiment of the present invention, the relative motion is provided by aeromechanical means.

Furthermore, in accordance with a preferred embodiment of the present invention, the active surface of the device is adapted to be occasionally relocated from point to point to clean localized portions of the surface to be cleaned.

Furthermore, in accordance with a preferred embodiment of the present invention, the cleaning head unit is supported by mechanical means.

Furthermore, in accordance with a preferred embodiment of the present invention, the cleaning head unit is supported by an air-cushion.

Furthermore, in accordance with a preferred embodiment of the present invention, the object to be cleaned is held with contact by mechanical means.

Furthermore, in accordance with a preferred embodiment of the present invention, the object to be cleaned is supported by non-contact means.

Furthermore, in accordance with a preferred embodiment of the present invention, the non-contact means comprises an air-cushion.

Furthermore, in accordance with a preferred embodiment of the present invention, the cleaning head is integrated in a non-contact supporting platform.

Furthermore, in accordance with a preferred embodiment of the present invention, the high-pressure outlet is elongated.

Furthermore, in accordance with a preferred embodiment of the present invention, said at least one lip comprises at least two elongated lips, whereby two opposing throat sections are defined having substantially equal widths.

Furthermore, in accordance with a preferred embodiment of the present invention, said at least one lip comprises at least two elongated lips, whereby two opposing throat sections are defined having different widths.

Furthermore, in accordance with a preferred embodiment of the present invention, said at least one lip comprises at least two elongated lips, whereby two opposing throat sections are defined, and wherein the passage is substantially perpendicular to the surface of the object to be cleaned.

Furthermore, in accordance with a preferred embodiment of the present invention, said at least one lip comprises at least two elongated lips, whereby two opposing throat sections are defined, and wherein the passage is tilted with respect to the surface of the object to be cleaned.

Furthermore, in accordance with a preferred embodiment of the present invention, the high-pressure outlet is annular.

Furthermore, in accordance with a preferred embodiment of the present invention, the active surface is flat.

Furthermore, in accordance with a preferred embodiment of the present invention, the active surface is arcuate.

Furthermore, in accordance with a preferred embodiment of the present invention, the active surface corresponds in shape to the shape of the surface of the object to be cleaned.

Furthermore, in accordance with a preferred embodiment of the present invention, said at least one high-pressure passage includes a flow restrictor.

Furthermore, in accordance with a preferred embodiment of the present invention, the flow restrictor exhibits self-adaptive return spring properties.

Furthermore, in accordance with a preferred embodiment of the present invention, the flow restrictor is an electromechanical control valve.

Furthermore, in accordance with a preferred embodiment of the present invention, the device is further provided with at least one gas evacuation passage, which includes a flow restrictor.

Furthermore, in accordance with a preferred embodiment of the present invention, at least two high-pressure outlets are provided, the outlets arranged in a substantially parallel orientation.

Furthermore, in accordance with a preferred embodiment of the present invention, the device comprises at least two high-pressure outlets, the outlets arranged in a substantially orthogonal orientation.

Furthermore, in accordance with a preferred embodiment of the present invention, at least one high-pressure outlet is provided that is divided into sectors that can be operated separately.

Furthermore, in accordance with a preferred embodiment of the present invention, the device comprises at least one high-pressure outlet that can be relocated to a new operational location between two consecutive cleaning sequences.

Furthermore, in accordance with a preferred embodiment of the present invention, the device comprises at least one high-pressure outlet that is parallel to the object where the object is oriented without any respect to gravity.

Furthermore, in accordance with a preferred embodiment of the present invention, there is provided a cleaning system for removing contaminants from a surface of an object to be cleaned, the system adapted to be fluidically connected to a high-pressure gas supply, the system comprising:
at least one cleaning head comprising at least one high-pressure passage with a predetermined miniature lateral scale with a high-pressure outlet for accelerating the gas, the high-pressure outlet characterized by at least one narrow lip, the outlet and the narrow lip defining an active surface,
supporting means for supporting the object to be cleaned;
relative motion means for providing relative motion between the surface of the object to be cleaned and said at least one cleaning head,
whereby when the active surface of the cleaning device is brought to a predetermined miniature gap from, and substantially parallel to, the surface, thus defining a throat section between said at least one narrow lip and the surface of the object to be cleaned, wherein the gap is the width of the throat section, and when the gas is accelerated to about sonic speeds at the throat section, lateral aeromechanic removal forces are produced that act on the contaminants.

Furthermore, in accordance with a preferred embodiment of the present invention, the system is configured for round objects to be cleaned.

Furthermore, in accordance with a preferred embodiment of the present invention, the system is configured for rectangular objects to be cleaned.

Furthermore, in accordance with a preferred embodiment of the present invention, the supporting means comprises a platform that supports the object, at least partly, without contact by an air-cushion from at least one side.

Furthermore, in accordance with a preferred embodiment of the present invention, the air-cushion is vacuum-preloaded.

Furthermore, in accordance with a preferred embodiment of the present invention, the supporting means comprises a platform that supports the object, at least partly, with contact.

Furthermore, in accordance with a preferred embodiment of the present invention, mechanical means employing friction are used to provide relative motion, by conveying the object.

Furthermore, in accordance with a preferred embodiment of the present invention, mechanical means employing gripping of the object are used to convey the object in order to provide relative motion.

Furthermore, in accordance with a preferred embodiment of the present invention, at least one cleaning head is movable in order to provide the relative motion.

Furthermore, in accordance with a preferred embodiment of the present invention, said at least one cleaning head and the object to be cleaned are movable in order to provide the relative motion.

Furthermore, in accordance with a preferred embodiment of the present invention, the system further comprises heating means.

Furthermore, in accordance with a preferred embodiment of the present invention, the heating means comprises a heater for heating the gas.

Furthermore, in accordance with a preferred embodiment of the present invention, the heating means comprises a heater for heating the surface of the object to be cleaned.

Furthermore, in accordance with a preferred embodiment of the present invention, wetting means are provided for wetting the surface to be cleaned, in order to reduce adhesive forces acting on the contaminants.

Furthermore, in accordance with a preferred embodiment of the present invention, an ionizer is provided for ionizing the gas.

Furthermore, in accordance with a preferred embodiment of the present invention, an actuator is provided for exciting the gas to high frequencies periodic fluctuations.

Furthermore, in accordance with a preferred embodiment of the present invention, an optical scanner is provided for inspecting the surface to be cleaned and monitoring removal of contaminants.

### BRIEF DESCRIPTION OF THE FIGURES

In order to better understand the present invention, and appreciate its practical applications, the following Figures are provided and referenced hereafter. It should be noted that the Figures are given as examples only and in no way limit the scope of the invention. Like components are denoted by like reference numerals.

FIG. 1a illustrates, in accordance with a preferred embodiment of the present invention, a general isometric view of an elongated cleaning head unit having a flat active surface.

FIG. 1b illustrates, in accordance with another preferred embodiment of the present invention, a general isometric view of an annular cleaning head unit having a flat active surface.

FIG. 1c illustrates a cross sectional view of the cleaning head unit shown in FIG. 1a, having a symmetric structure adjacent to a surface to be cleaned.

FIG. 1d depicts enlarged portion of the throat section of the cleaning head unit shown in FIG. 1c, with contoured throat section.

FIG. 1e depicts enlarged portion of the throat section of the cleaning head unit shown in FIG. 1c, with sharp throat section.

FIGS. 1f-h depict enlarged partial cross-sectional views of various throat section design options of the cleaning head unit shown in FIG. 1c, with sharp throat section.

FIG. 2a illustrates, in accordance with another preferred embodiment of the present invention, a side view of a cleaning head unit having an arcuate active surface.

FIG. 2b illustrates, in accordance with another preferred embodiment of the present invention, a bottom of the cleaning head unit having a bent active surface.

FIG. 3a illustrates, in accordance with another preferred embodiment of the present invention, a close cross-sectional view of the sharp throat section shown in FIG. 1e, where the width “a” of the pressure passage close to the throat section is larger than the throat section width “ε”, where a radial accelerated flow is generated.

FIG. 3b shows a close cross-sectional view of the sharp throat section shown in FIG. 1e, in accordance with another preferred embodiment of the present invention, where the width “a” of the pressure passage close to the throat section is of similar proportion to the throat section width “ε”, where flow separation zone is generated.

FIG. 3c shows a close cross-sectional view of the sharp throat section shown in FIG. 1e, in accordance with another preferred embodiment of the present invention, where the width “a” of the pressure passage close to the throat section is smaller with respect to the throat section width “ε”, where a shock wave is generated.

FIG. 4a illustrates a close cross-sectional view of a round shaped particle subjected to removal forces.

FIG. 4b illustrates a close cross-sectional view of a non-regular shaped particle subjected to removal forces.

FIG. 5a illustrates a cross-sectional view of the interaction between a particle and the boundary layer, where the particle's typical dimensions are larger that the boundary layer thickness.

FIG. 5b illustrates a cross-sectional view of the interaction between a particle and the boundary layer, where the particle's typical dimensions are smaller that the boundary layer thickness.

FIG. 6a illustrates a cross-sectional view of an operating cleaning head unit in motion, adjacent to a surface to be cleaned.

FIG. 6b illustrates schematically removal force characteristics with respect to the lateral direction that is parallel to the outgoing flow direction.

FIGS. 7a-c illustrate, in accordance with a preferred embodiment of the present invention, optional scanning modes, for covering cleaning areas.

FIG. 7d illustrates a bidirectional approach of applying the removal-force with respect to an elongated contaminating particle.

FIG. 8a illustrates, in accordance with a preferred embodiment of the present invention, a setup of a cleaning apparatus having in-contact platform and a cleaning head unit.

FIG. 8b illustrates, in accordance with another preferred embodiment of the present invention, a setup of a cleaning apparatus having non-contact platform and a cleaning head unit.

FIG. 8c illustrates, in accordance with another preferred embodiment of the present invention, a setup of a cleaning apparatus having non-contact platform, where the cleaning head unit is floating over a substrate to be cleaned.

FIG. 8d illustrates a bottom view of the cleaning head unit of the setup illustrates in FIG. 8c.

FIG. 9a illustrates, in accordance with a preferred embodiment of the present invention, a general top view of a non-contact round platform where an elongated cleaning head unit is integrated in the platform.

FIG. 9b illustrates, in accordance with another preferred embodiment of the present invention, a general top view of a non-contact round platform where a small movable cleaning head unit is integrated in the platform.

FIG. 9c illustrates, in accordance with another preferred embodiments of the present invention, several optional setups of cleaning apparatuses where two or more cleaning head units are incorporated.

FIGS. 10a-e illustrates, in accordance with several preferred embodiments of the present invention, setups of cleaning apparatuses presenting rotational cleaning motion, where various round platforms are implemented.

FIGS. 10f-j illustrates, in accordance with another several preferred embodiments of the present invention, setups of cleaning apparatuses presenting linear cleaning motion, where various non-contact platforms are implemented.

FIGS. 10k-n illustrate, in accordance with preferred embodiments of the present invention, setups of cleaning apparatuses presenting linear cleaning motion, where various in-contact platforms are implemented.

FIG. 11 illustrates, in accordance with a several preferred embodiments of the present invention, a cleaning system with peripheral auxiliaries.

FIGS. 12a-d illustrate, in accordance with preferred embodiments of the present invention, optional non-contact platforms that are based on fluidic return spring flow restrictors.

### DETAILED DESCRIPTION OF THE INVENTION AND FIGURES

In many manufacturing processes such as found at the semiconductor or the FPD industries, as well as other similar manufacturing processes (for example, manufacturing processes of Liquid Crystal Display (LCD) panels and glass surfaces, as well as media such as hard disks, CD & DVD, cardboards, and surfaces of optical lenses and devices), the surfaces of the products have to be extremely clean otherwise a critical reduction in yield may result. This is the reason why such manufacturing processes are carried out in clean rooms. However, although working in clean room conditions, there are many occasions in which the surfaces are contaminated, a fact that may severely affect the production yield.

The present invention provides a new and unique cleaning apparatus that can be used for cleaning surfaces from contaminating particles by using of a dry aero-mechanic method of cleaning. For the purpose of the present invention the term “cleaning” refers to removal of any kind of contaminants, for example particles or liquid, and to drying of a surface. A surface cleaning apparatus, as will be shown herein in several preferred embodiments, comprises a housing provided with cleaning head unit having an outlet that is connected to high pressure source and through which air (or other gas) is injected and preferably through other passages air is sucked by using vacuum forces.

In essence, the cleaning head unit of the present invention is aimed at producing a substantially parallel (hereinafter referred to as “parallel”) high-speed flow, in close proximity to the surface to be cleaned, in order to generate large parallel removal forces to disconnect the contaminating particles and to carry them away from the surface. The outlet's lips of the cleaning head unit are optimized in order to provide maximum parallel removal force but yet to minimize the throughput mass flow rate. These contradictory requirements can be fulfilled when the lips of the cleaning head unit are positioned in a very close proximity to the surface of the object to be cleaned. An important feature of the present invention is the establishment of a dynamic throat section of miniature dimensions between the lips of the cleaning head unit and the surface to be cleaned. This dynamic throat section has on one side lips of special aerodynamic design (pertaining to the cleaning head) and a flat surface on the other side, being the surface to be cleaned (such as a wafer FPD, and the like). This throat section also controls the throughput mass flow rate. The flow is rapidly accelerated along the throat section thus boundary layer thickness is maintained extremely small as maximum velocity is reached, and thus the pressure forces and the shear forces acting on the particles (hereinafter referred to as “removal forces”), are maximized. Miniature scales are considered with respect to the present invention, in order to significantly scale down aerodynamic features that are associated with the flow (such as the boundary layer thickness), and limit the throughput mass flow rate thus gaining a cost effective process and avoiding an increasing risk of contaminating the surface by introducing additional particles as a large volume of mass flow is involved. The aerodynamic design of the throat section is aimed at minimizing the boundary layer growth in order to gain:
Large velocity gradients and accordingly large shear forces that act on the particle.
Maximum pressure recovery to gain full potential side force that pushes the particle.
   This aim is obtained when in addition to the narrow width of the throat section the lateral length of the throat section is also maintained small, allowing the flow to rapidly accelerate to high speed. When the boundary layer thickness is small normal velocity gradients are large and accordingly the shear forces are significantly augmented. Further increase of the shear force can be obtained by creating a separated flow zone at the entrance to the throat section attached to the lips of the outlet of the pressure conduit of the cleaning head unit. In order to generate such a separated flow, the air must be accelerated to relatively high sub-sonic speeds inside the pressure conduit. Here the throat section width becomes effectively smaller by applying an aerodynamic mechanism (separated zone), and as a result, the removal forces are increased. When the flow speed at the outlet of the pressure conduit is further increased, another aerodynamic mechanism, a normal shock wave, is generated. This shock wave counteracts on the flow before impingement on the surface to be cleaned, and as a result, the throat section width becomes effectively smaller and accordingly the removal forces are increased. These mechanisms, can optionally be applied when extremely high removal forces are needed, (mostly for removing sub-micron particles). These mechanisms significantly reduce the throughput mass flow rate and are of significant importance with respect to risk of contact, as the distance from cleaning head unit to the surface of the object to be cleaned can be larger, but the effective throat section width is much smaller and it is the dominant scale with respect to aeromechanics.

Efficiency of the cleaning apparatus is greatly increased when the lips of the cleaning head unit are brought to a very close proximity to the surface to be cleaned. Without derogating generality, the throat section width (hereinafter denoted by “ε”), is about 30 microns or less, if fine particles are to be removed. For intermediate size particles the throat section width is preferably in the order of about 30 to 100 microns, and for coarse particles the throat section is preferably in the order of about 100 to 1000 microns. With respect to the small dimensions of the throat section width, the length of the throat section (it being basically the width of the lip of the pressure outlet of the cleaning head) is preferably also of a miniature scale, preferably in the same order of its width, in order to maximize the removal force, but also to limit the pressure-forces acting on the surface.

Accordingly, an elongated miniature cleaning area of two-dimensional nature is established, and when applying aeromechanic means at the edges of the elongated cleaning head unit to separate the internal process area from the outer area, the cleaning process of the present invention can be performed in a dynamically close miniature chamber. Be the cleaning head unit elongated or not, the dynamic isolation of internal clean area can be obtained by applying circumferential vacuum suction that removes the air with the removed particles The cleaning apparatus of the present invention can be used for point-to-point cleaning of individual particles, where particles position is detected by a particles inspection system. Alternatively, it can be used to clean an entire surface when relative motion between the surface to be cleaned and the cleaning head unit is provided. When it is desired to clean entire surfaces, it is recommended to use an elongated cleaning head unit, to facilitate a faster cleaning process. Obviously, rather than using one elongated cleaning head unit, it is possible to use several cleaning head units simultaneously.

To optimize the cleaning process, It is preferable that the cleaning head is moved substantially parallel to the surface to be cleaned, it being flat or contoured, and the direction of motion must be substantially parallel to the direction of the flow at the throat section, but also large angles of up to about 45 and more degrees are effective as long as the entire surface is scanned. In order to maximize the cleaning performance it is recommended to make a cycle of cleaning where scanning motion over the substrate is performed several times. When applying such a cleaning cycle it is preferable to provide a scanning motion at different lateral directions.

The supply pressure plays a major role with respect to the cleaning performance. The task of cleaning can be classified as following with respect to the rule of the supply pressure:
For low cleaning requirements a pressure of up to 5 bars is suggested.
For moderate cleaning requirements a pressure of up to 20 bars is suggested.
For high cleaning requirements a pressure of up to 100 bars is preferred.
   This classification is also coupled to the throat section width “ε”, where it is preferable that the higher the cleaning requirements are, the smaller “ε” is, and accordingly the throat section length is shorter. Generally speaking, higher cleaning performance is needed as the task of particles removal is extended to smaller scale contamination particles. When the supply pressure is more than 2 bars or when evacuation by vacuum suction is implemented, the pressure ratio between the two sides of the throat section is large enough to generate a high speed of flow, a sonic-speed at the throat section area and super-sonic speed further downstream.

Air or an alternative gas, such as N₂ or He (other gases may be used too) from a high pressure reservoir may be used in order to (a) provide inertial conditions if required (b) take advantage of the thermodynamic properties of the gases.

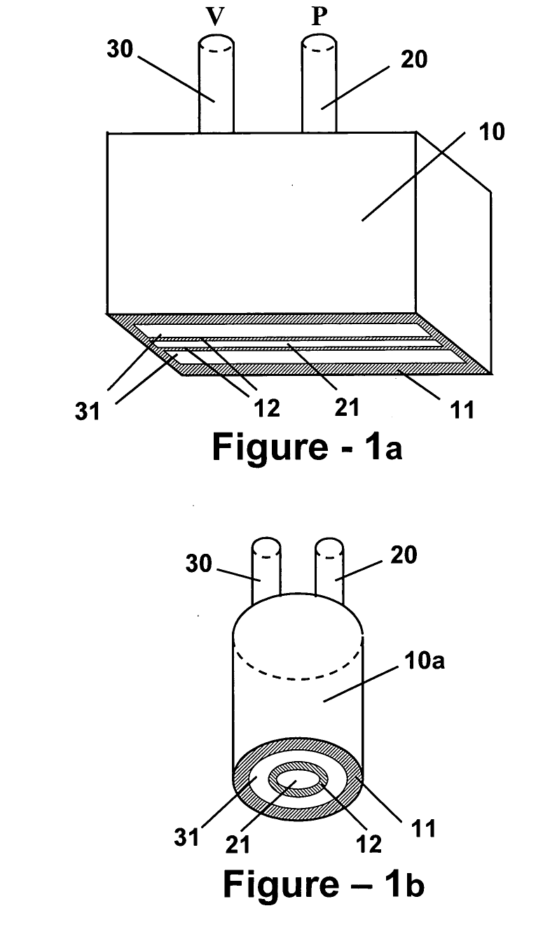

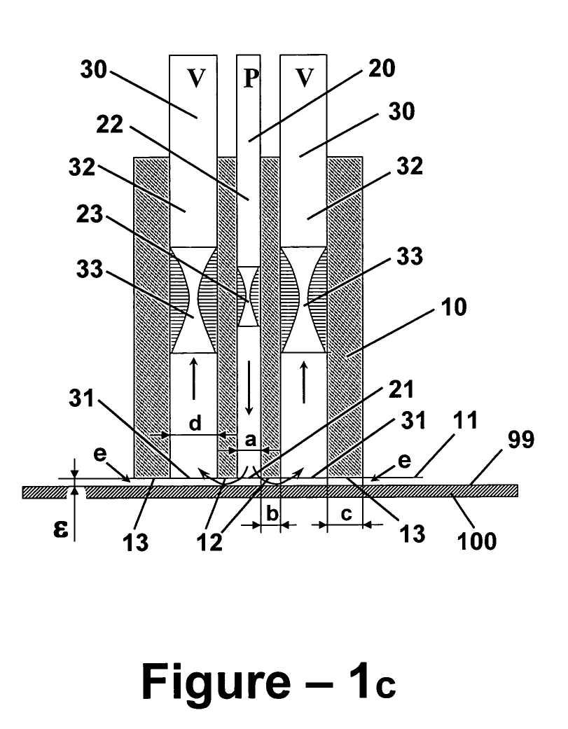

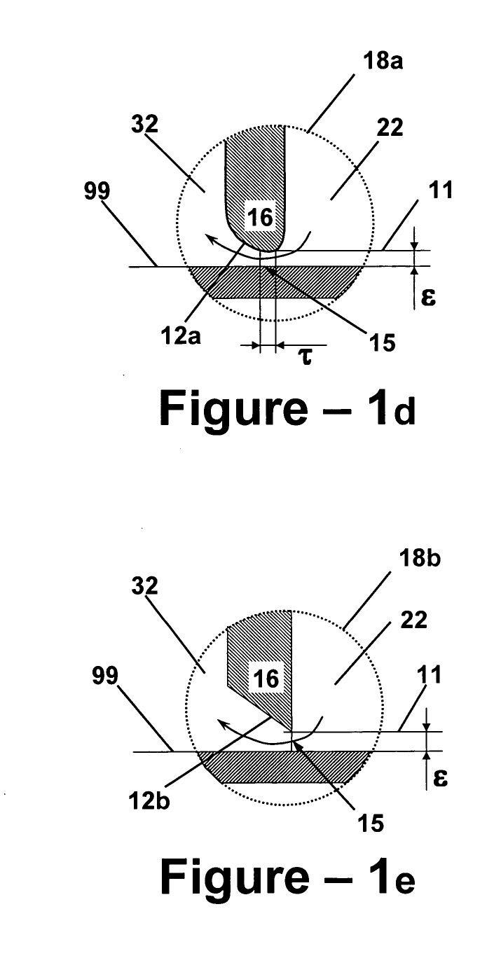

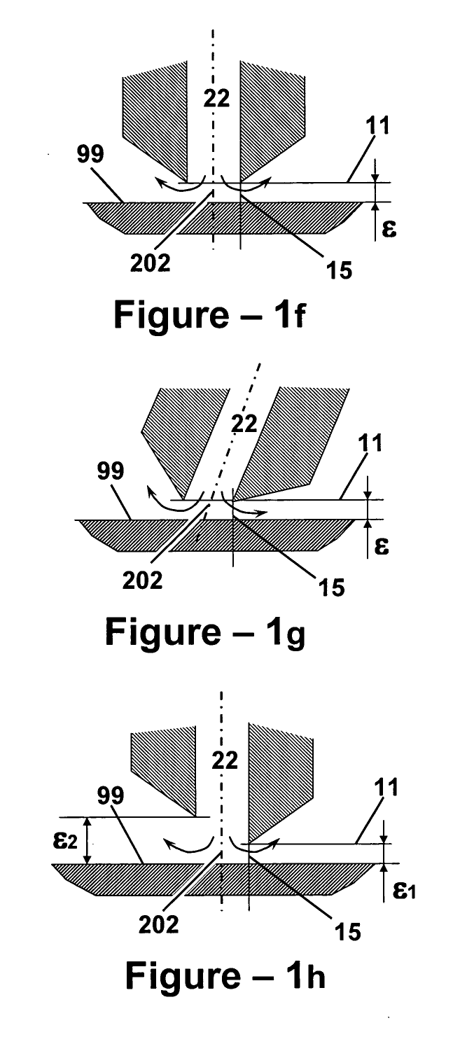

Reference is now made to FIG. 1a illustrating schematically an isometric view of an elongated cleaning head unit 10 of the air-scraper apparatus in accordance with a preferred embodiment of the present invention. This elongated, straight, version of the cleaning head unit is suitable for cleaning large areas by applying a relative scanning motion to the surface to be cleaned. It has connectors for pressure 20 and vacuum 30 supply. The cleaning head unit 10 facing surface 11 is seen at the bottom. Typically, the facing surface 11 has one essentially central pressure outlet 21 and two (optional) vacuum outlets 31, separated from the pressure outlet by lips 12 of the cleaning head unit 10, where the lips 11 are geometrically presented on facing surface 11. Cleaning of flat surfaces such as Wafers or FPDs can be implemented during the manufacturing process, or to be applied in a frequent routine, cleaning contact surfaces of wafers and FPD handling equipment in order to reduce backside contamination arising from inadvertent physical contact.

FIG. 1b illustrating schematically an isometric view of a round-shaped cleaning head unit 10a of the air-scraper apparatus in accordance with another preferred embodiment of the present invention. This annular version of the cleaning head unit is suitable for point-to point cleaning, in particular when inspection system is involved in the cleaning process, detecting the presence of contaminants in specific locations. It has similar connectors for pressure 20 and vacuum 30 supply. The facing surface 11 of the round-shaped cleaning head unit 10a is seen from the bottom. Typically, the facing surface 11 has one substantially central pressure outlet 21, surrounded by an annular vacuum outlet 31, the annular lips 12 of the cleaning head unit 10 are geometrically presented on facing surface 11 and separate the central pressure outlet 21 from the surrounding annular vacuum outlet 31.

FIG. 1c schematically illustrates a cross sectional view of the elongated cleaning head unit 10 shown in FIG. 1a. The cleaning head unit 10 has a mirror symmetry structure. However, in most aspects the cross sectional view of the round-shaped cleaning head unit 10a shown in FIG. 1b is similar. The cleaning head unit 10 has basically two different types of pipes connectors, one connector or more for high-pressure supply 20 and one connector or more for vacuum supply 30. High pressure passage 22 fluidically connects the high-pressure supply 20 with the pressure outlet 21 at the cleaning head unit 10 facing surface 11, and vacuum passage 32 fluidically connects the vacuum supply 20 with the vacuum outlet 31 at the facing surface 11 of the cleaning head unit 10. The facing surface 10 is positioned substantially parallel and in a close proximity to the surface 99 of the object 100 to be cleaned. The gap between the facing surface 11 of the cleaning head unit 10 and the surface 99 to be cleaned is denoted hereafter by the letter Greek letter “ε”. The outlets 21, 31, and the lips 12 define a miniature chamber with the facing surface 11. The lips 12 are the edges of the wall that separate the high-pressure passage 22 from the vacuum passage 32. The lips 12 have a typical width “b”, the high-pressure outlet 21 having a typical width “a”, and the vacuum outlet 31 having a typical width “d”. The cleaning head unit 10 has also outer walls with rims 13 having a typical width “c”. The outer wall edges 13 may optionally be included in the facing surface 11, but it can also be designed at a distance (“e”) from the surface 99, which is larger than “ε”. It is an option to provide a flow restrictor 23, like a SASO device (which is a mechanical flow restrictor, see WO 01/14782, WO 01/14752 and WO 01/19572, and corresponding U.S. Pat. No. 6,644,703 and U.S. Pat. No. 6,523,572, all incorporated herein by reference), or a pressure control valve (usually electrically operated) inside the high-pressure passage 22, in order to provide a fluidic return spring nature to the cleaning head unit. To save vacuum resources, it is an option to equip another, different flow restrictor 33, preferably also s SASO nozzle of smaller aeromechanical-resistance with respect to the SASO nozzle that is selected for the high pressure passage, or other flow control valve inside the vacuum passage 32.

A dynamically close miniature chamber is created by dynamic isolation of the close cleaning area. It can be obtained by applying circumferential vacuum suction 31 that sucks away the air together with the removed particles and also sucks a limited amount of ambient air through the passage 13 with a width “e”, but without much interaction with the outer atmosphere.

When the cleaning head unit 10 is placed in close proximity to the surface 99, the high pressure air flows down from passage 22 toward the outlet 21, passes through a very small gap “ε” that is created between the lips 12 and the surface 99, and is sucked away by the vacuum outlet 31 through the passage 32 that communicates with vacuum connector 30 (linked to a vacuum reservoir). The miniature zone created between the lips 12 and the surface 99 will be referred hereafter as the “throat section” zone. As the cleaning head unit 10 has a mirror symmetry structure, two opposing miniature cleaning zones are created below the two opposing throat sections. The throat section has a very narrow width, denoted by the letter “ε”. The throat section zone is the place where the high removal forces are generated. The surface 99 of the object 100 to be clean and the lips 12 of the cleaning head unit 10 are preferably not both at rest, one of them or both are moved in a lateral motion in order to provide the relative scanning motion, necessary to cover and clean large areas or to move from one point to another (in a point-to-point mode of cleaning). Although symmetric set up is shown in FIG. 1c, the two opposite throat section of the cleaning head unit can be different, where, for example, the throat section that first scans the contaminated surface is designed to clean large particles first and the second (the opposing one), preferably of smaller throat section width is designed to clean smaller scale particles. In general, it is possible to create a multi stage cleaning process using more than one cleaning head unit. Alternatively, a multi stage cleaning process can be provided, by regulating both the pressure and the throat section width, and repeating the scan several times.

FIG. 1d schematically illustrates a focused cross sectional view of a contoured throat section 18a of the cleaning head unit 10 of the air-scraper 30 apparatus in accordance with another preferred embodiment of the present invention. It has contoured lips 12a. Air flow is accelerated rapidly from the high-pressure passage 22 through the throat section 15 created between the surface 99 to be cleaned and the lips 12a of the wall 16 between passages 22 and 32, and finally sucked away through vacuum passage 32. The contoured throat section 15 has a tiny width “ε” and a very short length denoted by the letter “τ”. As cleaning is performed at the throat section zone, the removed particles are evacuated through the vacuum passage 32.

FIG. 1e schematically illustrates a focused cross sectional view of a sharp throat section 18b of the cleaning head unit 10 of the air-scraper apparatus in accordance with another preferred embodiment of the present invention. It has sharp lips 12b. The flow is accelerated rapidly from the high-pressure passage 22 through the throat section 15 created between the surface 99 to be cleaned and the sharp lips 12b of the wall 16 between passages 22 and 32, and finally sucked away through the vacuum passage 32. The sharp throat section 15 has a tiny width “ε”. However, with respect to the contoured lips 12a, in this design it is intended to create a vanishing throat section length (there is still a minimum length due to manufacture limitations). As cleaning is performed at the throat section zone, the removed particles are evacuated through the vacuum passage 32.

FIG. 1f illustrates, in accordance with a preferred embodiment of the present invention, a cross sectional view close to the outlet of the high-pressure passage 22 of the cleaning head units shown in FIGS. 1a and 1b. The center-line 202 of passage 22 is substantially perpendicular to the surface 99 of the object to be cleaned. This cross-sectional view has at least one (15) of two opposing throat sections, where the flow directions at each of the opposing throat sections are substantially opposite. The facing surface 11 of the cleaning head unit is parallel to the surface of the object to be cleaned, and the distance between these two surfaces is substantially uniform, being the throat section width S. FIG. 1g illustrates, according to another preferred embodiment of the present invention, a similar design to FIG. 1f, but the center-line 202 of passage 22 is substantially tilted with respect to the surface 99 of the object to be clean. FIG. 1h illustrates, according to another preferred embodiment of the present invention, a similar design to FIG. 1f, applicable for a substantially two dimensional cleaning head unit designs such as the elongated cleaning head unit shown in FIG. 1a, but the throat section width ε1 of the throat section 15 is smaller than the opposing throat section having a throat section width ε2. Such a design facilitates a two-stage cleaning process where as the cleaning head unit is in relative lateral motion to the left, with respect to the object to be cleaned, large particles are first removed at lower risk of any mechanical contact between the cleaning head and the large particles, that may lead to a severe damage to the object to be cleaned or to the cleaning head unit, and following that stage, the smaller cross section 15 of width ε2, having higher performance with respect to removal of particles removes the smaller particles.

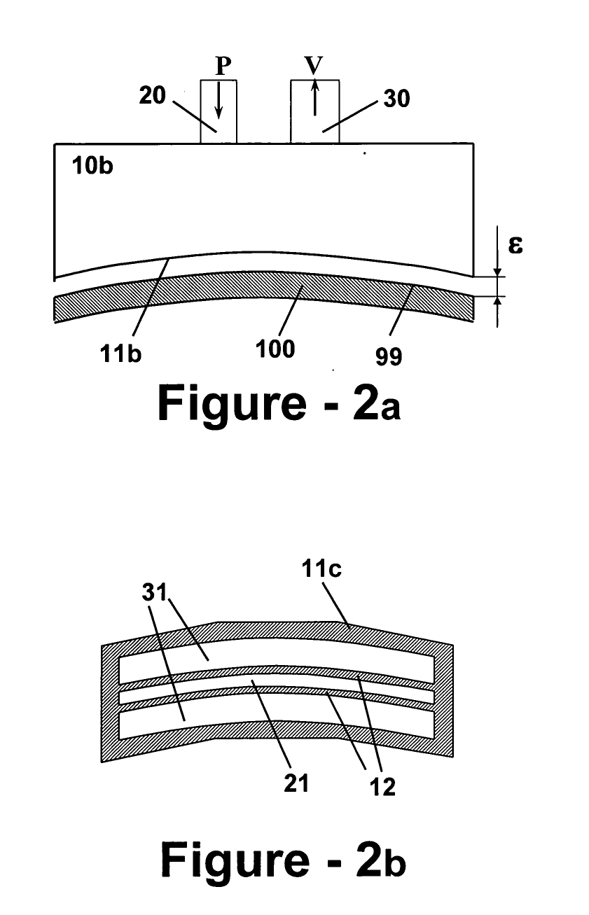

Reference is now made to FIG. 2a illustrating a side view of a cleaning head unit of the air-scraper apparatus in accordance with another preferred embodiment of the present invention. This cleaning head unit 10b has a non-flat facing surface 11b corresponding to the non-flat surface 11b of the object to be cleaned 100. Cleaning of non-flat surfaces such as optical lenses can be implemented during the manufacturing process of the lenses or integrated in a system that uses optical lens, for clearing the optical view that may be subjected to constant contaminating condition such as dusty environment.

Reference is now made to FIG. 2b illustrating a side view of a cleaning head unit of the air-scraper apparatus in accordance with another preferred embodiment of the present invention. This cleaning head unit has a non-straight facing surface 11c, suitable for cleaning corresponding surfaces.

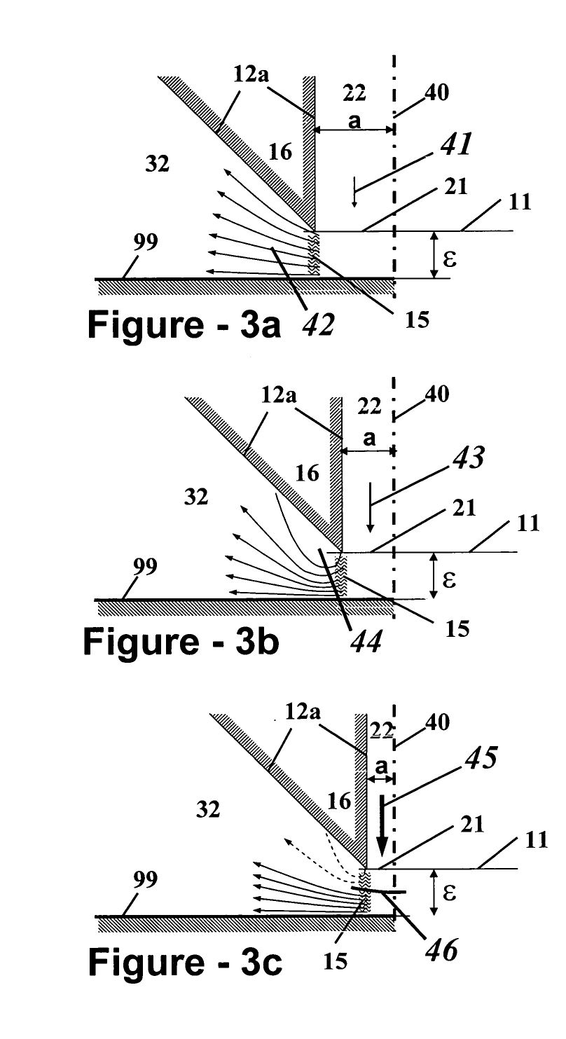

The high removal forces are generated at the throat section area along a very short length. In order to maximize cleaning performance, the flow-field can be manipulated. Reference is now made to FIG. 3a depicting an enlarged portion of the sharp edge throat section shown in FIG. 1b. FIG. 3a schematically illustrates a focused cross sectional view a sharp throat section 18b, one of two opposing throat sections of the cleaning head unit with sharp lips 12b. The flow is accelerated rapidly from the high-pressure passage 22 through the throat section 15 created between the surface 99 to be cleaned and the sharp lips 12b of the wall 16 between passages 22 and 32, and finally sucked away through the vacuum passage 32. The sharp throat section 15 has a tiny width “ε”. When, with respect to another preferred embodiment of the present invention, the lateral width “a” (the lateral scale) of the high-pressure passage 22 (at outlet 21, close to the throat section area), is large with respect to “ε”, a low-speed flow towards the surface 99 is developed inside high-pressure passage 22, as indicated by the small arrow 41, thus the dynamic pressure at outlet 21 (close to the surface 99), is very small with respect to the stagnation pressure. Accordingly, a “radial” flow pattern 42 is developed. Where the fluid start to accelerate only at the throat-section area.

In FIG. 3b the lateral width “a” of the high-pressure passage 22 (at outlet 21, close to the throat section area), is of a similar scale with respect to “ε”, that is roughly the same length. Accordingly, high-speed flow towards the surface 99 is developed inside 22, as indicated by the larger arrow 43, and flow separation zone 44 attached to the throat section sharp edge is created. As a result, an aerodynamically shaped throat section of much smaller effective width exists. Thus, by regulating “a”, the effective width of the throat section can be significantly larger than its physical width. It has mainly two beneficial contributions: (a) the boundary layer thickness is compressed, thus small scale particle removal is more efficient, (b) from system reliability point of view and for the sake of risk reduction (of mechanical damage), it is preferable to work at a wider mechanical “ε” (the distance between object to be cleaned and the cleaning head unit), but yet to provide performance that is related to significantly smaller effective throat section width.

In FIG. 3c the lateral width “a” of the high-pressure passage 22 (at outlet 21, close to the throat section area), is smaller than “ε”. Accordingly, high-speed flow (close to sonic speed), towards the surface 99 is developed inside 22, as indicated by the much larger arrow 45. At the outlet 21 the flow is further accelerated to a relatively low super-sonic speed. As the flow has to stop and to change it's direction, a stagnation zone is created, below outlet 21, but part of the pressure recovery is provided by standing shock-wave 46 mechanism. As the shock wave Mach number is close to sonic Mach number (M=1), the pressure losses through the shock wave are not significant. The shock wave is another mechanism that provides an aerodynamically shaped throat section of much smaller effective width. Practically speaking, a factor of about 2 between the mechanical and the effective width can be obtained. In this case also, by regulating “a”, the effective width of the throat section can be significantly larger than its mechanical width, but also the flow regime is “switched”. The benefits of reducing the throat section effective width is already summarized with respect to FIG. 3b.

High removal forces are needed to provide efficient cleaning of few micrometer & sub-micron particles. The removal forces acting on a particle are built from two contributions, acting in the same (stream-wise), direction:
“Drag” or pressure side forces
Shear forces
   The present invention main objectives is to maximized these forces, and also optimize the overall removal forces by merging, for example, the peak performance of the two forces to be located at same place.

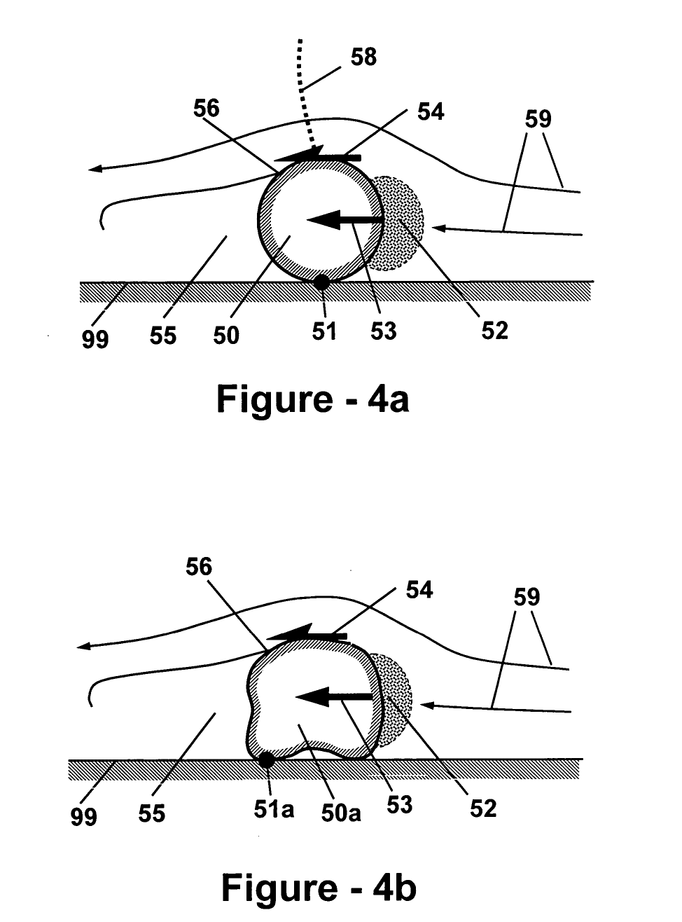

Reference is made to FIG. 4a, illustrating a schematic close view of a single spherical particle 50 adheres to the surface to be clean 99 and subjected to a lateral flow characterized by stream-lines 59. This is a miniature close view of the flow regime close to the particle that is located at the throat section zone (not seen in the drawing). As the particle having a three-dimensional character poses as an obstacle to the flow, the stream-lines 59 open out also in three-dimensional manner (only one stream line up wise is drawn, for brevity). Just downstream of the particle, flow separation 56 occurs and a miniature wake flow 55 is generated. A pressure removal force 53 is generated when the flow stops just before the particle, a stagnation zone 52 is developed where high recovered pressure forces are acting (stream-wise), on the particle. On the other side, much lower pressure is acting on the particle at it downstream side that is subjected to the separated flow. Moreover, as the flow is a sonic flow, a standing shock wave 58 attached to the top surface of the particle can be formed as the flow is further accelerated (to low super-sonic speeds). In that case, the pressure on the wake side is further reduces. The net stream-wise pressure force is, generally speaking, the difference between the pressure acting on the upstream side to the pressure acting on the downstream side of the particle. The stream-wise shear force 54 acting on the top particle 55 top surface attributed to viscosity. Accordingly it is related to the thermodynamic properties of the gas (the viscous coefficient) and depends on the normal (to the surface) velocity gradients.

These two complementary stream-wise removal forces generate a resultant side force that tends to disconnect the particle from the surface by slippage. However in many cases this is not the dominant removal mechanism, as the particle can firstly disconnect by rolling with respect to the point of rotation 51, as it is subjected to aeromechanic moments (notice that the shear force span is larger as much as twice with respect to the pressure force). When the particle 50 is a perfect sphere, the adhesion force cannot provide much resistance to the aeromechanic moments as the span of the adhesion forces with respect to the point of rotation 51 is small. FIG. 4b shows a similar situation as shown in FIG. 4a, but the particle 50a is of non-regular shape. In that case, with respect the to the shape of a specific particle, the point of rotation 51a is offset with respect to the adhesion forces. Accordingly the adhesion force can provide resistance to the aeromechanic moments as the span of the adhesion-forces with respect to the point of rotation 51a can be significantly large. When such adhesion moments are developed, the removal forces needed to disconnect the particle by rolling mechanism may be extremely larger with respect to the removal forces needed to disconnect a similar in size spherical particle.

Usually the larger the particle is, more irregularities in shape are found and the smaller the particle is, more regular and spherical particles are found. Generally speaking, the role of particle removal suggests that the removal forces needed for removing a particle (with respect to particle side) are increased as the typical dimension of the particle is decreased. Combining these two generalized statements, it seems that particles shaping effects mostly affect large particles where the removal forces needed are relatively smaller on one hand, and on the other hand, relatively small shaping effects affect small particles where also without the severe augmentation of removal requirements due to shaping, large removal forces are needed for providing an efficient process of cleaning.

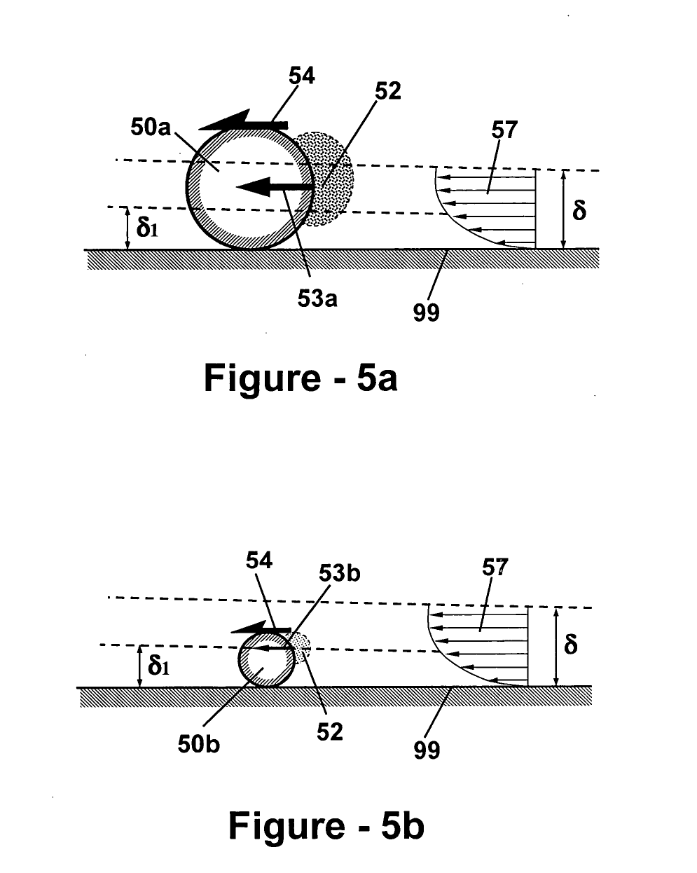

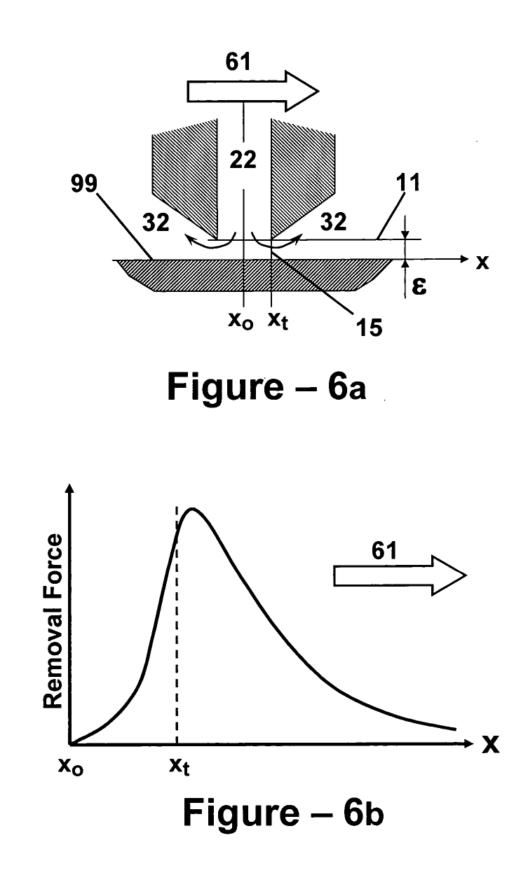

An aerodynamic issue of significantly high importance with respect to the cleaning efficiency of the apparatus and method of the present invention is the interaction of the particles with the boundary layer. FIG. 5a schematically illustrates such an interaction where the particle 50a typical scale is larger than the thickness “δ” of the boundary layer 57. There are many useful definitions for boundary layer thickness in the literature. However, with respect to removal forces, a practical thickness, “δ₁”, will be defined, where “δ₁” is the scale where the inertia of the boundary layer is relatively weak, thus the strength of the pressure force 53a significantly deteriorates. When a large particle interacts with the boundary layer, the pressure recovery exceeds almost a full potential. It clarifies directly the role of pressure where the higher the pressure supply (or the stagnation pressure), the higher the pressure lateral forces acting on the particle. The shear force 54 depends on the local velocity gradients, and it is not significantly affected by the weak portion of the boundary layer (the sub-layer that is close to the surface 99). Furthermore, local higher shear forces are developed with respect to the shear force that would have been developed on a smooth surface, due to boundary layer local narrowing at the top of the particle. In the case of relatively large particles, both pressure and shear forces are directly related to the active area where the forces are superimposed. Generally speaking, as the typical scale decreases, these forces decrease by a square of that typical scale.

FIG. 5b schematically illustrates a case where a particle 50b has a typical scale that is smaller than the thickness “δ” of the boundary layer 57. In this case the particle is mostly subjected to the weak potion of the boundary layer bounded by the practical thickness “δ₁”, thus the strength of the pressure force 53b significantly deteriorates and pressure recovery does not reach its full potential. Still, the shear force 54 may not significantly be affected by the weak portion of the boundary layer. As a result, in the case of relatively smaller particles, only the shear force is directly related to the active area (reduced by square with the decrease of the particle typical scale), and the pressure force decays substantially faster when the typical scale is decreased. Accordingly, for a large particle the pressure force is the dominant part of the removal forces, but for increasingly small particle removal requirements, the shear force starts to play a major role.

The scaling between the particle typical scale and the boundary layer is of great importance with respect to efficiency of removing small-scale particles, in particular sub-micron particles. It is mostly important in connection with the present invention to reduce the physical scales of the throat section zone, and to obtain a miniature active cleaning area at the throat section zone. When the width of the throat section is extremely small, a feature preferably achieved by implementing one of the above mentioned aerodynamic mechanisms to create a narrower throat section effective-width, the boundary layer thickness also becomes smaller. As the length of the throat section become shorter (preferably a sharp throat section) the flow rapidly accelerates along a very short downstream distance to a sonic flow. According to the role of boundary layers thickness growth, the shorter the distance from the origin of the flow, the smaller the boundary layer thickness. Miniature scales and rapid acceleration (less than 10 micro-meters is needed to accede sonic speed), provide almost vanishing boundary layer thickness at the throat section zone, where the flow reaches a sonic speed. The throat section zone is the most effective zone with respect to removal forces and further downstream the removal forces become smaller. It is of course related to particle—boundary-layer interaction as was already mentioned hereinabove. As the boundary layer thickness is smaller, smaller particles may be subjected to the full potential lateral pressure force without significantly deteriorating effects resulting from the weak flow portion of the boundary-layer.

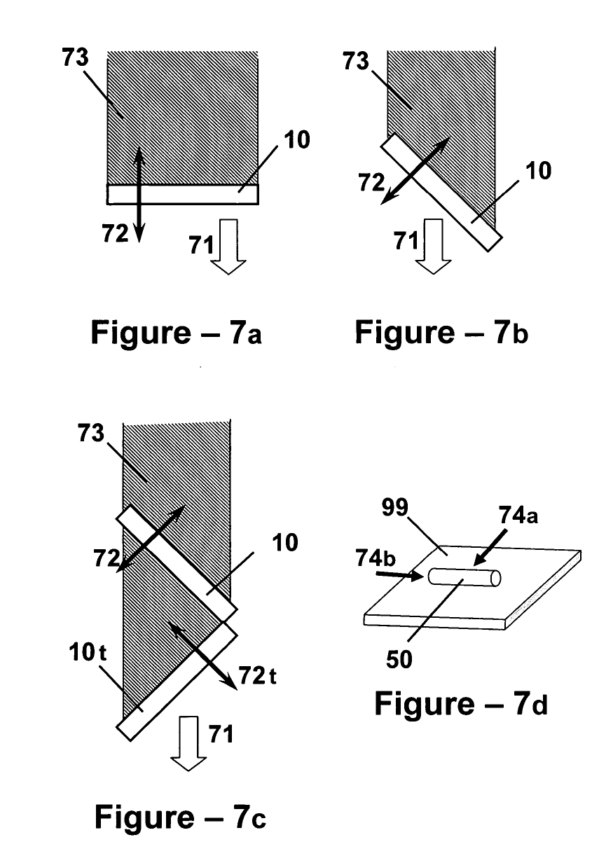

In order to perform an effective cleaning process aimed at cleaning large surfaces, it is suggested to perform a scanning motion with the cleaning head unit of the present invention. Relative motion between the cleaning head unit and the surface to be cleaned is employed. FIG. 6a illustrates surface 11 of a symmetric cleaning head unit close to and facing surface 99 of the object to be cleaned. Facing surface 11 is defined by the lips of the cleaning head unit, where both the outlet of the high-pressure passage 22 and the inlet of the vacuum passage 32 are present on the surface 11. The narrow passage that is created between the sharp-edge lips of the cleaning head unit and the surface 99 to be cleaned define the throat section 15. The relative motion is provided by moving the cleaning head unit laterally, in a direction that is denoted by the arrow 61. It is recommended that the direction of the relative scanning motion be substantially parallel to the direction of the high-speed flow (for indication, see the arrows between 22 and 32). The lateral motion is characterized as a substantially parallel motion between the facing surface 11 and the surface 99 to be cleaned, as gap ε controls the flow and affects the cleaning efficiency. It is convenient to define an axis “X” that is parallel to the scanning motion 61, with an origin Xo at the symmetry line, and Xt is the distance from the origin to the sharp edge of the throat 15. FIG. 6b illustrates schematically the spatial distribution of removal forces. At the origin Xo the removal force is zero and it reaches its maximum value very close to Xt. For larger X, the removal forces become reduced. However when a relative motion is provided, each point on the surface to be clean is eventually subjected to the maximum removal forces. Therefore, the velocity of the scanning is preferably limited in order to allow enough time to for the removal forces to act on the particles. As the time scale of the removal mechanism is very fast due to the ultra-low-mass of miniature particles, practically any convenient velocity may be applied. The most effective direction of motion with respect to the cleaning process efficiency is believed to be obtained when the direction of scanning motion is parallel to the lateral direction of the high speed flow that generates the removal forces.

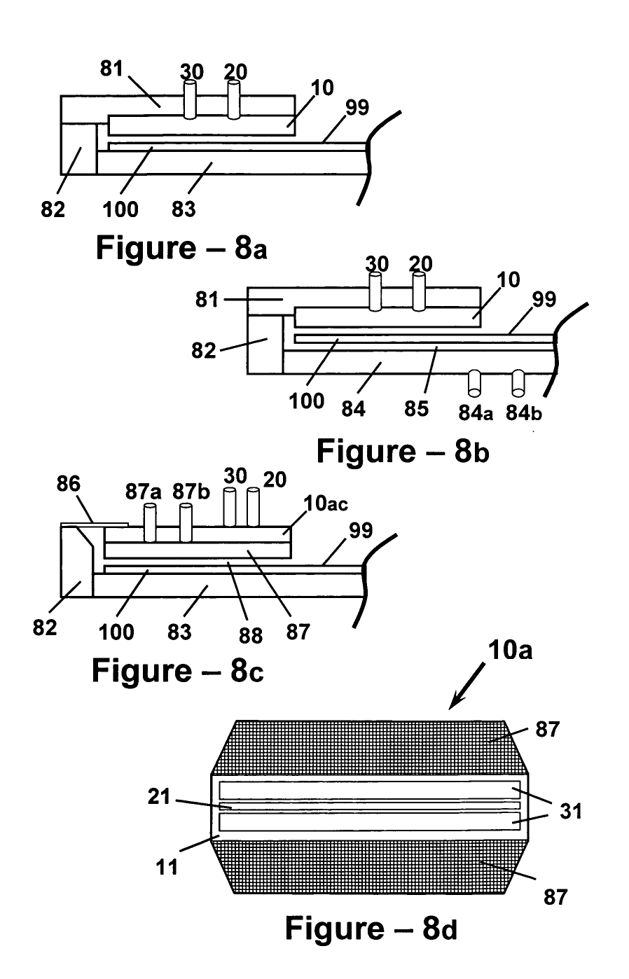

FIG. 7a-d illustrates some proposed relative motion effects. FIG. 7a illustrates a basic relative scanning motion where the cleaning head unit 10 travels in a lateral direction 71 substantially parallel to the most effective cleaning directions 72 (two opposing directions are acceptable if the cleaning had unit has a symmetric structure), thus geometrically speaking, the coverage area 73 during the cleaning process is believed to be the wider available with respect to the cleaning head unit length. FIG. 7b illustrates a case where the cleaning head unit 10 travels in a lateral direction 71 that is not parallel to the most effective cleaning directions 72, thus geometrically speaking, the coverage area 73 during the cleaning process is reduced. However also when an angle of 45° is applied between directions 71 and 72, still more that 70% of the scanning efficiency is maintained. In order to optimize the cleaning process efficiency, a setup where the cleaning apparatus is equipped with two orthogonal cleaning head units is suggested. FIG. 7-c illustrates such a setup where two cleaning head units 10 (where the removal force directions are denoted by the arrow 72), and 10t (where the removal force directions are denoted by the arrow 72t), are positioned orthogonally and both are oriented at an angle of 45° with respect to the scanning motion 71. The reason for such a setup is evident when reviewing FIG. 7d. This figure schematically illustrates a common situation where an elongated particle 50 lying over the cleaning surface 99 needs to be removed. When the removal force acts on that elongated particle on its short aspect (74a) the resistance to the rolling mechanism of removal is relatively small, but when the removal force acts on the elongated aspect of the particle (74b), resistance to the rolling mechanism of removal is significantly increased. Accordingly, the use of bidirectional cleaning process as illustrated by the setup shown in FIG. 73, improves the cleaning process. Another alternative for this setup is to use one cleaning head unit but perform dual stage cleaning process where in between the two cleaning stages the orientation of the cleaning head is altered. It has to be emphasized that for the purpose of the present invention, the phrase “relative scanning motion” means that either the cleaning head unit is kept at rest and the object to be clean is moved, or the cleaning head unit is moved and the object to be clean is kept at rest, or when a more complex motion is implemented and both cleaning head unit and the object are moved in relative motion between them.

Other important issue with respect to the present invention is the thermal conditions that exist during the cleaning process. Air or other gas that is used in the cleaning process can be pre-heated. In that case, removal forces that depend on the thermodynamic properties of the gas (such as viscosity or density) are augmented or at least do not severely deteriorate. Nevertheless, the main reason for heating the gas is for reducing the adhesion forces. If the heated air heats the particles and the surface to be clean underneath it to a temperature of more than 100° C., water trapped between the particles and the surface evaporates. As the water disappears, the capillary portion of the adhesion force not longer exists. Capillary force is the significant part of the adhesion force and accordingly it makes the task of particle removal easier when it disappears. Another alternative is to pre-heat the object to be clean and/or to heat it during the cleaning process in order to evaporate the water and to diminish significantly the adhesion force. Heating can be performed using an in-contact platform where heating elements are used (heat conduction mechanism), or by pre-heating air that is used to produce an air-cushion, when a non-contact platform is used (heat convection mechanism). On the other hand, it is also an option to spray the surface with water to reduce the capillary forces, or to apply other solutions, in order to weaken the adhesion forces. There are many known commercial solutions that are used for that end. However such an approach that involves wet conditions around the particles is not preferable as it leads to a semi-dry cleaning process and it is difficult to exercise. In addition, it is also an option, with respect to reducing adhesion force, to add ionizer to the flow in order to reduce the electrostatic adhesion force.

In order to maximize removal forces, it is an option to provide periodic fluctuations to the flow, to be effective at the throat section area. It can be done by acoustic means or by using electromechanical means (including piezoelectric elements). From an aerodynamic point of view, periodic (time dependent) fluctuations affect temporarily the boundary layer thickness and the velocity gradients close to the surface. Moreover, periodic fluctuation frequencies can be correlated with the miniature scales of the smaller particles where the removal task becomes harder. It means that high frequencies can be effective for removing miniature (submicron) particles, but the operational frequencies must be lower than a critical frequency, since fluid acts like a low-pass filter and does not response to extremely high frequencies.

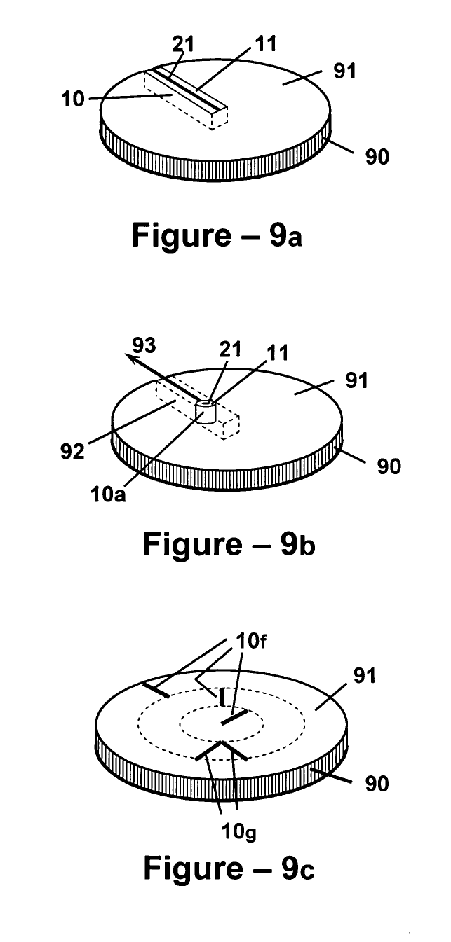

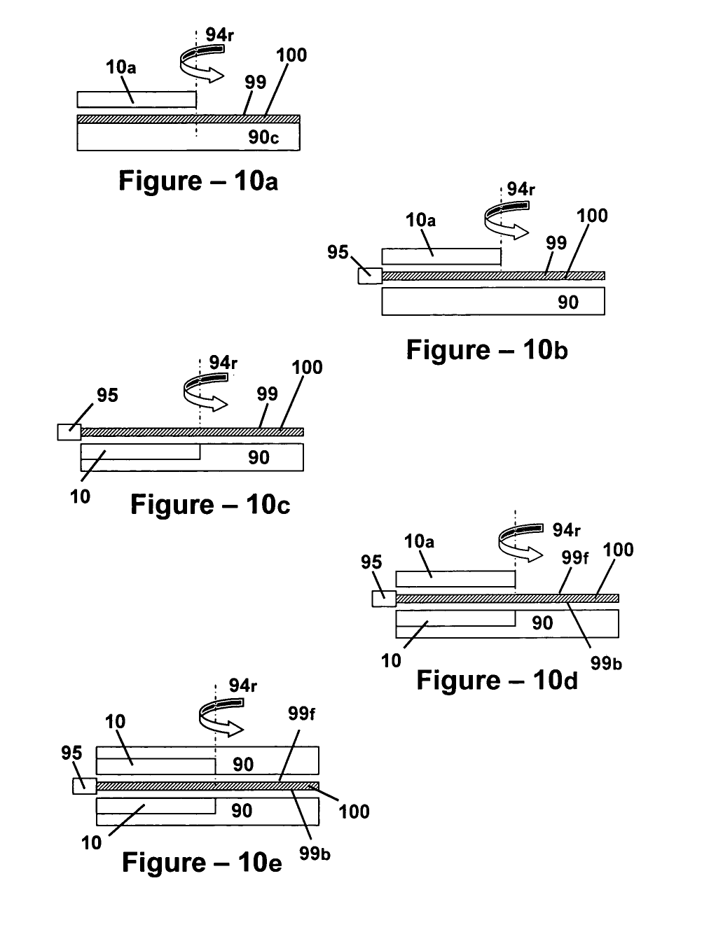

A cleaning system in accordance with the present invention comprises a cleaning apparatus that has at least one cleaning head unit, an optional platform for supporting the object to be clean, with or without contact, where the surface of the that object is safely held in close proximity to the cleaning head unit, and moving means for providing a substantially parallel relative motion, linear or rotational, between the cleaning head unit and the surface of the object to be cleaned. There are many set-ups being consistent with this definition. With respect to the cleaning apparatus of the present invention and without derogating generality, several preferred embodiments of the present invention are presented in FIGS. 8-10.

FIG. 8a illustrates a preferred embodiment of the present invention, a setup where the object to be cleaned 100 is held in position from its backside in physical contact to platform 83. This setup is equipped with a cleaning head unit 10 having pressure inlet 20 and vacuum outlet 30. The cleaning head unit 10 is held in close proximity to the surface 99 to be cleaned of object 100. An arm 81, optionally being a robotic arm, holds the cleaning head unit 10. Arm 81 is connected to a vertical element 82, being a mechanism for controlling the gap between the cleaning head unit 10 and the surface 99 to be cleaned of the object 100.

FIG. 8b illustrates, with accordance with another preferred embodiment of the present invention, a setup resembling the setup described with respect to FIG. 8a, where the object to be cleaned 100 is held in position using a non-contact platform 84. The non-contact platform 84 has an inlet 84a for supplying pressurized-air to maintain an air cushion or air-bearing 85 created between the top surface of the platform 84 and surface 99 to be cleaned of object 100, and optionally a vacuum outlet 84b, if the air-cushion 85 is preloaded by vacuum (Pressure-Vacuum (PV) air cushion, see PCT/IL02/01045, titled High-Performance Non-Contact Support Platforms (Yassour et al.), published as WO 03/060961, incorporated herein by reference). In this set up, control of the gap between the stand-alone cleaning head unit 10 and the surface 99 to be cleaned of object 100 can be provided be adjusting the gap of the air cushion 85. It can be done by regulating the pressure supply 84a, or the vacuum 84b, or both.

FIG. 8c illustrates, in accordance with another preferred embodiment of the present invention, another setup resembling to the setup described with respect to FIG. 8a, where the object to be cleaned 100 is held with contact from its backside to platform 83. In this case the cleaning head unit 10c is supported from both sides by an air-cushion that is created between the surface 99 to be cleaned of object 100 and the facing surface of the active plates 87 attached to both sides of the cleaning head unit 10c. The active plates 87 generate a supporting air-cushions 88 from both sides of the cleaning head unit 10c, for example in the manner described in PCT/IL02/01045, incorporated herein by reference. Each of these plates has an inlet 87a for supplying pressurized-air and maintaining an air-cushion 88 created between the bottom-side facing surface of the cleaning head unit 10c to the front-side surface 99 of the object 100 to be cleaned, and optionally a vacuum outlet 87b, if the air-cushion 88 is preloaded by vacuum (Pressure-Vacuum (PV)-air-cushion). In this set up, control of the gap between the cleaning head unit 10c and the surface 99 to be cleaned of object 100 can be provided be adjusting the gap of the air cushion 88. It can be done by regulating the pressure supply 87a, or the vacuum 87b, or both. In this setup the cleaning head unit 10c is floating over the air-cushion 88 created above the surface 99 of object 100, following that surface 99. In order to provide free floating with respect to the vertical direction, the cleaning head unit 10c is connected to the element 82 by a flexure bar 86 that is flexible with respect to the vertical direction but stiff with respect to lateral directions. FIG. 8d illustrates a bottom view of the cleaning head unit 10c of the setup disclosed in FIG. 8c. This bottom view shows the facing surface 11c of the cleaning head unit 10c. Similarly to FIG. 1c, the facing surface 1c contains a high-pressure outlet 21 and vacuum suction inlets 31, but in order to enable floating of the cleaning head unit 10c, two active plates 87 are integrated at both sides of the cleaning head unit 10c. The two active plates 87, which may be employing techniques described in PCT/IL02/01045, incorporated herein by reference, generate the air-cushions for supporting the cleaning head unit 10c symmetrically.

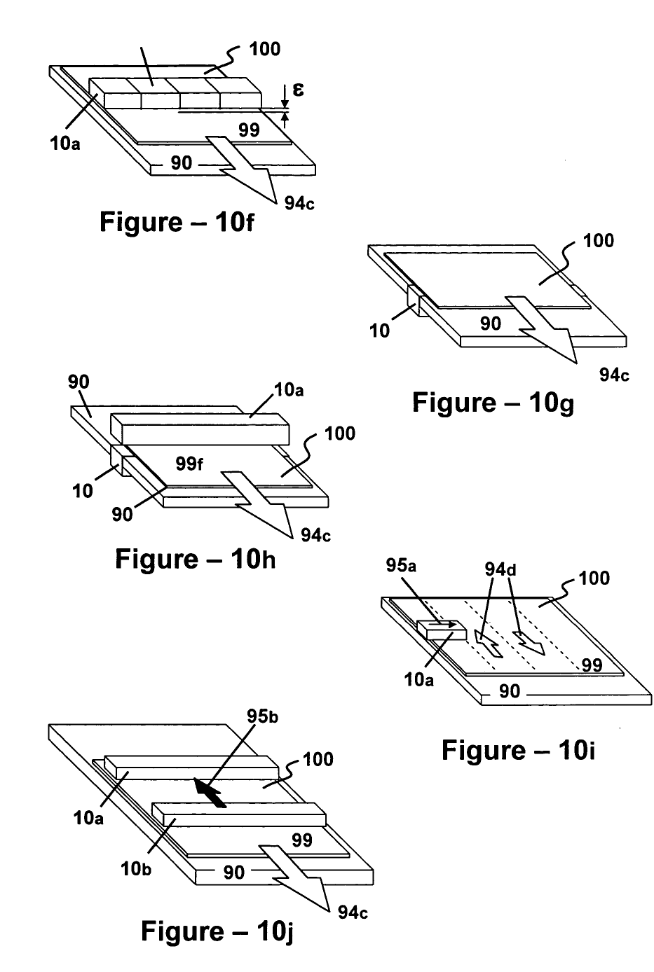

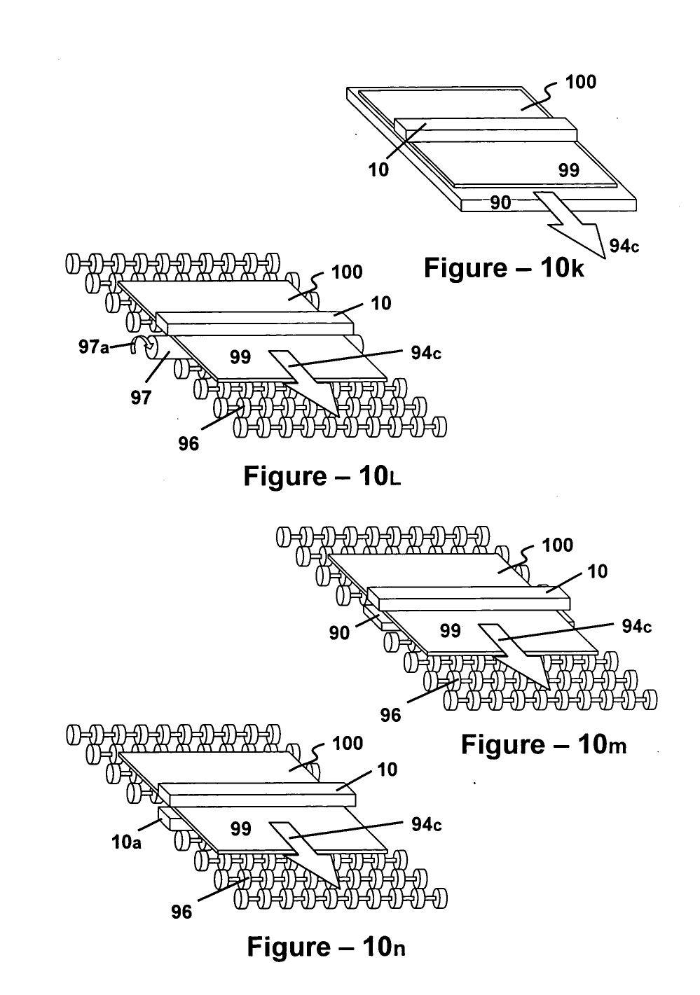

In accordance with another preferred embodiment of the present invention, it is convenient to design a setup where the cleaning head unit is integrated with the non-contact platform of dry cleaning apparatus. Without derogating generality, several integral platforms having an integral cleaning had unit, are shown in FIGS. 9a-c. FIGS. 9a-c illustrate circular platforms where the object to be cleaned is present above a non-contact platform and a relative motion between the object and the platform is provided. FIG. 9a illustrates, in accordance with a preferred embodiment of the present invention, a circular non-contact platform 90 having an active surface 91 with an integral cleaning head unit 10. Such a setup is preferable for cleaning round objects such as silicon wafers. The elongated cleaning head unit 10 has a facing surface 11, where also the outlet 21 of the high-pressure passage of the cleaning head unit 10, is shown. The facing surface 11 of the cleaning head unit 10 is integrated in surface 91 of the non-contact platform 90.

FIG. 9b illustrates, in accordance with another preferred embodiment of the present invention, a circular non-contact platform where a small traveling cleaning head unit 10a having a round outlet 21 of the high pressure passage (of the cleaning head unit 10), is integrated in a round non-contact platform 90 having an active surface 91. The cleaning head unit 10a is of much smaller size with respect to the radius of the non-contact platform 90. The facing surface 11 of the cleaning head unit 10a is included in the active surface 91 of the non-contact platform 90. In order to provide radial scanning motion, the cleaning head unit is moved during the cleaning process along a radial slider 92. In this case, coverage of the entire surface to be cleaned is completed by simultaneously turning the object to be clean (not seen in the figure).

FIG. 9c illustrates, in accordance with another preferred embodiment of the present invention, several options where more than one cleaning head units are integrated within the non-contact platform 90, where the facing surface of each cleaning head unit is incorporated in the active surface 91 of the non-contact platform 90. One option is to use several cleaning head unit segments 10f arranged in a radial orientation but at different angles, where each segment cleans an annular slice and all the segments together provide full coverage of the surface to be cleaned. Still, coverage of the entire surface to be cleaned may also be completed by turning the object to be clean (not seen in the figure). Another option is to apply removal forces acting in two substantially perpendicular directions, by replacing each of the integral segments 10f with two segments 10g, having substantially perpendicular orientation (only the central slice is shown). In this case cleaning process efficiency may be improved as explained with respect to FIG. 7d hereinabove.

FIGS. 10a-h illustrate, in accordance with another preferred embodiment of the present invention, optional setups that can be applied for the dry cleaning system where it is intended to clean flat surfaces. Without derogating generality, FIGS. 10a-e illustrate setups employing rotational scanning motion that are typical for the semiconductors industry (round wafers), and FIGS. 10f-h illustrate setups employing linear scanning motion that are typical for the FPD industry (wide-format substrates).

FIG. 10a illustrates, in accordance with a preferred embodiment of the present invention, a setup having circular geometry for front-side cleaning where a cleaning head unit 10a is facing the surface 99 of the object to be cleaned that is held down in contact, to the platform 90c of the dry cleaning system. The cleaning head unit can be equipped with side non-contact active plates that generate air-cushion to support the cleaning head unit as described in FIGS. 8c-d. In that case, either the platform 99 is rotating or the cleaning head unit 10a is rotating, or both, in order to provide the relative scanning motion 94r.

FIG. 10b illustrates, in accordance with another preferred embodiments of the present invention, a setup having circular geometry for front-side cleaning where a stand-alone cleaning head unit 10a is facing the surface 99 of the object to be cleaned that is supported by a non-contact platform 90 of the dry cleaning system. In this setup (and also with respect to FIG. 10c and 10d), it is preferable to implement the Pressure-Air (PA)-type supporting air-cushion, or the Pressure-Vacuum(PV)-type (vacuum preloading) air-cushion that clamps the object at bi-directional manner (see PCT/IL02/01045, incorporated herein by reference). In this setup, either the cleaning head unit 10a is rotating, or the object to be cleaned 100 is rotating, or both, in order to provide the relative scanning motion 94r. Rotational motion to the round object 100 can be provided by a rotating mechanism such as a drive-wheel 95 attached to the edge of the round object 100 (such as silicon wafer). Other rotational drive mechanisms that may alternatively be implemented, include rotating circumferential-ring that clamps the object or any other in-contact mechanism that clamp the object from it's backside. Another option is to apply a totally non-contact fluidic mechanism that imposed rotating shear forces to rotate the object. Other mechanism may also be used, remaining within the scope of the present invention.

FIG. 10c illustrates, in accordance with another preferred embodiment of the present invention, a setup having circular geometry for backside cleaning where the cleaning head unit 10 is integrated within the non-contact platform 90 of the dry cleaning system. The integral cleaning head unit 10 is facing the backside surface 99 of the object to be cleaned 100 that is supported by a non-contact platform 90 of the dry cleaning system. In this setup, only the object to be cleaned 100 is rotating in order to provide the relative scanning motion 94r. Again, rotational motion to the round object 100 can be provided by a rotating mechanism such as a drive-wheel 95 that is attached to the edge of the round object 100 (such as silicon wafer). Other rotational drive mechanisms were discussed with reference to FIG. 10b.

FIG. 10d illustrates, in accordance with another preferred embodiment of the present invention, a setup having circular geometry for cleaning both the front-side and the backside of a round object. This setup includes both a cleaning head unit 10a for cleaning the front-side 99f of object 100, and an opposing integral cleaning head unit 10, integrated within the platform 90 of the dry cleaning system, for cleaning the backside 99b of object 100. The object to be cleaned 100 that is supported by a non-contact platform 90 of the dry cleaning system. In this setup, only the object to be cleaned 100 is rotating in order to provide the relative scanning motion 94r. Yet again, rotational motion to the round object 100 can be provided by a rotating mechanism such as a drive-wheel 95 that is attached to the edge of the round object 100 (such as silicon wafer). Other rotational drive mechanisms were disclosed with respect to FIG. 10b.

FIG. 10e illustrates, with respect to another preferred embodiment of the present invention, a setup having circular geometry for cleaning both the front-side 99f and the backside 99b of a round object 100. This setup includes two opposing integral cleaning head units 10, integrated in two opposing plates 90 of a dual-side non-contact platform (it is a mirror-symmetry platform), of the dry cleaning system. The object to be cleaned 100 is supported by a dual-side non-contact platform of the dry cleaning system. In this case it is preferable to implement the dual side PP-type (pressure preloading) air-cushion, or a dual-side vacuum-preloaded PV-PV type air-cushion (see PCT/IL02/01045, incorporated herein by reference). These dual-side supporting air-cushions provide inherently stable non-contact platform for high performance cleaning. In this setup, only the object to be cleaned 100 is rotating in order to provide the relative scanning motion 94r. Again, rotational motion to the round object 100 can be provided by a rotating mechanism such as a drive-wheel 95 that is attached to the edge of the round object 100 (such as silicon wafer). Other rotational drive mechanisms were disclosed with respect to FIG. 10b.

Without derogating the generality, FIGS. 10f-j illustrates setups employing linear scanning motion suitable for the FPD industry (wide-format thin substrates). where non-contact platforms are implemented. FIG. 10f illustrates, in accordance with another preferred embodiments of the present invention, a setup having rectangular geometry for front-side cleaning of rectangular thin substrates such as FPD, where an elongated cleaning head unit 10a is facing the front-side 99 of the object 100 to be cleaned that is supported by a non-contact platform 90 of the dry cleaning system. The cleaning head unit 10a may be divided to several sectors 10s. This case is similar in most details to the setup described in FIG. 10b, but here linear motion is provided. In this setup (and also with respect to FIGS. 10g-10j), it is suggested to implement the supporting PA-type air-cushion, or the PV-type (vacuum preloading) air-cushion (see PCT/IL02/01045, incorporated herein by reference) that clamps the object at a bidirectional manner. In this setup, either the cleaning head unit 10a is linearly moved, or the object to be cleaned 100 is moved in linear motion, in order to provide the relative scanning motion 94c. Linear motion to the object 100 can be provided by using various types of linear-motion systems and grippers. Another option is to apply a totally non-contact fluidic mechanism that imposed shear forces to linearly drive the object.

FIG. 10g illustrates, in accordance with another preferred embodiment of the present invention, a setup having rectangular geometry for backside cleaning of rectangular substrates such as FPD, where an elongated integral cleaning head unit 10 is integrated within the non-contact platform 90 of the dry cleaning system. The integral cleaning head unit 10 is facing the backside 99 of the object 100 to be cleaned as it supported by a non-contact rectangular platform 90 of the dry cleaning system. This case is similar in most details to the setup described in FIG. 10c, but here linear motion is provided. Other relevant details are similar to the setup described in FIG. 10f.

FIG. 10h illustrates, in accordance with another preferred embodiments of the present invention, a setup having a rectangular geometry for cleaning both the front-side 99f and the backside (not shown in the figure) of a thin rectangular object 100 such as FPD. This setup includes both a cleaning head unit 10a for cleaning the front-side 99 of object 100, and an opposing cleaning head unit 10, integrated within the non-contact platform 90 of the dry cleaning system, for cleaning the backside of object 100. The object to be cleaned 100 is supported by a non-contact rectangular platform 90 of the dry cleaning system. This case is similar in most details to the setup described in FIG. 10d, but here linear motion is provided. Other relevant details are similar to the setups described in FIGS. 10f and 10g.

FIG. 10i illustrates, in accordance with another preferred embodiments of the present invention, a setup having rectangular geometry for front-side cleaning of rectangular substrates such as FPD, where much shorter cleaning head unit 10a with respect to FPD width is provided. In this setup the process of cleaning is performed consecutively on longitudinal slices; The object to be cleaned 100 is moved forward and backward (94d) and the cleaning head unit is moved laterally (95a) to new lateral position in a predetermined time frame between the two opposing movements. Such a setup can reduce significantly the mass flow rate of the cleaning system. Other relevant details are similar to the setups described in FIGS. 10f.

FIG. 10j illustrates, in accordance with another preferred embodiments of the present invention, illustrates a setup having rectangular geometry for front-side cleaning of rectangular substrates such as FPD, where two elongated cleaning head units 10a and 10b are provided. In this setup the process of cleaning is performed in a parallel manner, where the cleaning process is completed by moving longitudinally (94c) to only half of the substrate length. Such a setup provides a significantly smaller footprint of the cleaning system (by 25% or so). Another alternative to obtain similar reduction of the cleaning system footprint is by using only one moving cleaning head unit 10b where at the same time that the substrate moves forwards 94c half way of the substrate length, the cleaning head unit 10b is moved backwards 95b half way. Other relevant details are similar to the setups described in FIGS. 10f. Similar effects can be obtained by dividing laterally the elongated cleaning head unit into several sectors (see sectors 10s at FIG. 10f), where the sectors are operated one after the other. In such arrangement, no moving elements are involved in the cleaning process thus reducing the risk of drop-down contamination.

Without derogating the generality, FIGS. 10k-n illustrate setups employing linear scanning motion especially appealing for the FPD industry (wide-format thin substrates) where in-contact platforms are implemented. FIG. 10k illustrates, in accordance with a preferred embodiments of the present invention, a setup having rectangular geometry for front-side cleaning of the surface 99 of object 100. The object 100 is held with contact (optionally by vacuum means) to a moving table and the scanning motion is a forward motion 94c of the table that carries the object 100 to be cleaned. Other relevant details are similar to the setups described in FIGS. 10f.

FIG. 10L illustrates, in accordance with another preferred embodiments of the present invention, a setup having rectangular geometry for front-side cleaning of the surface 99 of object 100. The object 100 is optionally conveyed before and after passing in the cleaning area by a standard wheel conveyor 96. In addition, a driving cylinder 97 is provided, and it is opposing the cleaning head unit 10, and the object 100 is moving linearly in between. Cylinder 97 moves the object 100 forward 94c with respect to the rotational velocity 97a. The cylinder rotational velocity 97a is synchronized with the motion of the wheels conveyor 96. FIG. 10m illustrates, in accordance with another preferred embodiments of the present invention, a setup having rectangular geometry for front-side cleaning. This setup is similar to the setup described in FIG. 10l, but instead of having a driving cylinder, the cleaning area is supported by non-contact platform 90 that is opposing to the cleaning head unit 10, and the object 100 is moving linearly in between. FIG. 10n illustrates, in accordance with another preferred embodiments of the present invention, a setup having rectangular geometry for dual sides cleaning. This setup is similar to the setup described in FIG. 10l, but instead of having a driving cylinder, two opposing cleaning head units 10 (for cleaning the front-side of object 100) and 10a (for cleaning the backside of object 100) are provided, and the object 100 is moving linearly in between.

The orientation of the cleaning head with respect to the surface to be cleaned may vary. The device of the present invention can operate horizontally, vertically and in fact in any desired orientation.

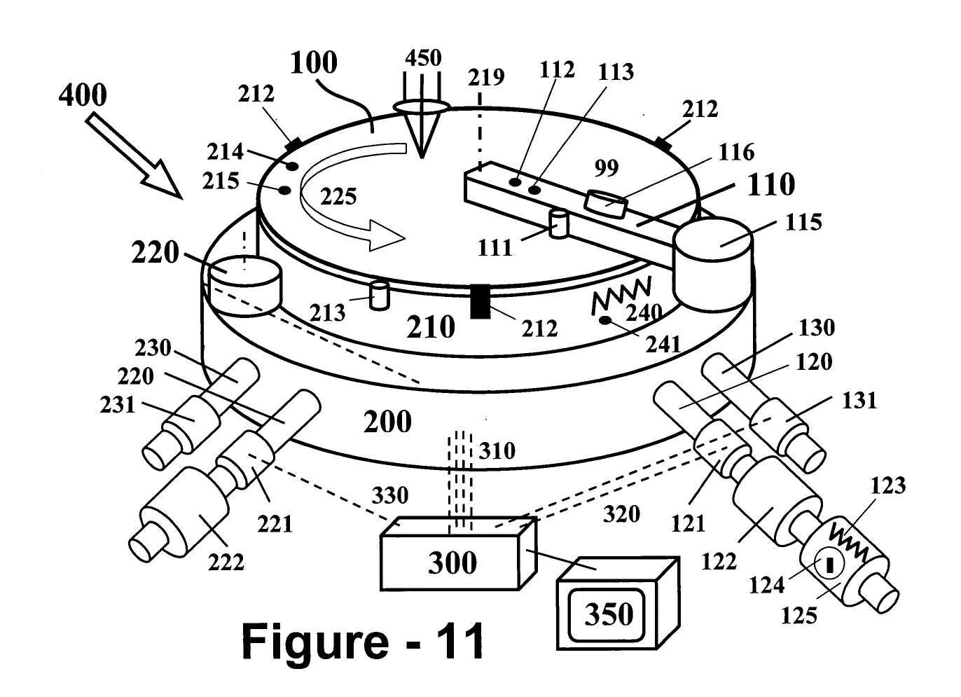

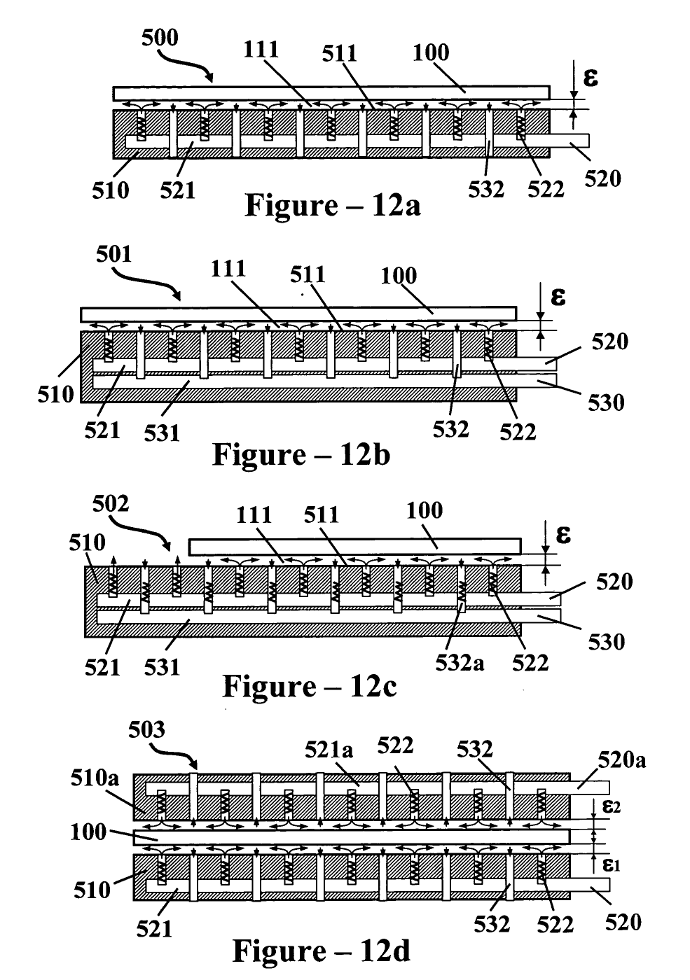

Reference is now made to FIG. 11 illustrating, in accordance with a preferred embodiment of the present invention, a dry cleaning system 400. The dry cleaning system 400 has a base 200 having an internal volume large enough to host different components and subsystems in a compact manner. On top of base 200, the dry cleaning system 400 has a PV-type non-contact supporting platform 210. The non-contact supporting platform 210 rotates in direction 225 driven by a driving mechanism 220. During the cleaning process, the platform 210 is in relative rotational motion with respect to base 200 and to the cleaning head unit 110. Platform 210 may be supported by mechanical or aeromechanical means to balance its body-weight. The object to be cleaned 100 is laterally clamped by 3 edge elements 212. Elements 212 provide also centricity alignment for object 100 with respect to the center axis 219 of the non-contact platform 210. Elements 212 serve also as landing pins for loading and unloading of object 100. The object to be cleaned 100 is vertically supported without contact by PV-air-cushion that is provided by non-contact platform 210. Proximity sensor 213 is attached to the non-contact platform 210 in order to sense the distance between the facing surface of the non-contact platform 210 and the backside surface of the object to be cleaned 100, to enable close loop control of the gap of the supporting air-cushion. Heating elements 240 and temperature sensor 241 are integrated within the platform 210.

Cleaning head unit 110 of the dry cleaning system 400 in accordance with a preferred embodiment of the present invention is placed in close proximity above the surface 99 to be clean of object 100, stiffly connected to a supporting mechanism 115. The supporting mechanism 115 is capable of regulating the distance between the facing surface of the cleaning head unit 110 and the surface 99 of the object to be clean 100. Proximity sensor 111 is attached to the cleaning head unit 110 in order to provide control of this distance. In addition, the supporting mechanism 115 can rotate the cleaning head unit 100 sideward, to allow free loading and unloading of object 100 by bringing it laterally to central position, moving it vertically down and put it on landing elements 212 and vise versa.

Pressurized gas (such as air) is supplied to the cleaning head unit 110 by pressure pipe-line 120, having pressure control valve 121 and sub-microns filter 122. It is preferable that the filter 122 will be mounted after the valve 121 to reduce risk of contamination. Similarly, vacuum is supplied to the cleaning head unit 110 by vacuum pipe-line 130, having a vacuum control valve 131. Both the pressurized air and the vacuum are supplied to the cleaning head unit 110 through the base 200 and the supporting mechanism 115. Pressure sensor 112 and vacuum sensor 113 are integrated in the cleaning head unit 110. The pressurized air can be manipulated by unit 116 for providing high frequency periodic fluctuations. It can be done by acoustic device (electromechanical device) or piezoelectric device. In addition, a utility unit 125 can be fluidically connected at the entrance to pipeline 130. The utility unit 125 may include heating elements 123 and ionizer 124.

Pressurized gas (such as air) is supplied to the PV-type non-contact platform 210 by the pressure pipe-line 220, having a pressure control valve 221 and a sub-microns filter 222. It is preferable that the filter 222 will be mounted after the valve 221 to reduce risk of contamination. Similarly, vacuum is supplied to the PV-type (vacuum preloaded) platform 210 by vacuum pipe-line 230, having a vacuum control valve 231. Both the pressurized air and the vacuum are supplied to the PV-type non-contact platform 210 through the base 200. Pressure sensor 214 and vacuum sensor 215 are integrated in the PV-type non-contact platform 210.

Central control unit 300 of the dry cleaning system is designed to control the cleaning process of the dry cleaning system 400 by connections 310 and the external supply pipes by connections 320, 330, to provide all information needed to control the cleaning process. It also includes connection to external equipment and computer 350 for monitoring and communication.

Central control unit can be an external unit or it may be internally installed inside base 200. Accordingly valves 121 and 131 as well as valves 221 and 231 can be assembled inside base 200. In addition, an optical scanning device 450 may be incorporated with the cleaning system 400 to provide either lateral the location of the contaminating particles (in particular when point-to-point cleaning process is applied) and/or to provide pre- and post-process analysis of the cleaning process.

According to a preferred embodiment of the present invention, a PA-type non-contact platform is applied for supporting the object to be cleaned. FIG. 12a illustrates a cross sectional view of a typical PA-type non-contact platform 500 having a rigid assembly 510 and an integral pressure manifold 521. The pressure manifold 521 is fed with pressurized gas (such as air), through pressure line 520 that is connected to a pump (not seen in the figure). The PA-type air-cushion 111 supports the object to be cleaned 100, where the pressurized air is introduced to the PA-type air-cushion 111 through a plurality of pressure conduits 522, each equipped with a flow restrictor (such as SASO nozzle), functions as a fluidic return spring, having an exit at the top surface 511 of assembly 510. The PA-type air-cushion 111 is generated between the bottom side of the object to be clean 100 to the top surface 511 of assembly 510, and the distance between the two surfaces is the gap ε of the PA-type air-cushion 111. The PA-type air-cushion 111 is of local balance nature as the assembly 510 has a plurality of evacuation to atmosphere conduits 532 having an exit at the top surface 511 of structure 510.

According to another preferred embodiment of the present invention, a PV-type (vacuum preloaded) non-contact platform is applied for clamping without contact the object to be cleaned, in cases where the non-contact platform is fully covered. FIG. 12b illustrates a cross sectional view of a typical PV-type non-contact platform 501 having a rigid assembly 510, an integral pressure manifold 521 and an integral vacuum manifold 531. The pressure manifold 521 is fed with pressurized gas (such as air), through the pressure connector 520 that is connected to a pump (not seen in the figure). The vacuum manifold 531 is connected through the vacuum connector 530 to a vacuum-pump (not seen in the figure). The PV-type air-cushion 111 clamps the object to be cleaned 100 without contact, where the pressurized air is introduced to the PV-type air-cushion 111 through a plurality of pressure conduits 522, each of it is equipped with a flow restrictor (such as SASO nozzle), functions as a fluidic return spring, having an exit at the top surface 511 of assembly 510. The PV-type air-cushion 111 is of local balance nature as assembly 510 has a plurality of vacuum suction conduits 532 having an exit at the top surface 511 of structure 510. The PV-type air-cushion 111 is generated between the bottom side of the object to be cleaned 100 and the top surface 511 of assembly 510, and the distance between the two surfaces is gap ε of the PV-type air-cushion 111. As seen in FIG. 12b, all the outlets of pressure conduits 522 at surface 511 and all the outlets of vacuum conduits 532 at surface 511 are covered by object 100 that is clamped without contact by the PV-type air-cushion at a distance ε of from surface 511.

According to another preferred embodiment of the present invention, a PV-type non-contact platform is applied for clamping without contact the object to be cleaned, in cases where the non-contact platform is not fully covered. FIG. 12c illustrates a cross sectional view of a typical PV-type non-contact platform 502, where most details are similar to FIG. 12-b. However, not all the outlets of pressure conduits 522 at surface 511 and not all the outlets of vacuum conduits 532 at surface 511 are covered by object 100 (as shown in the left side of platform 502, FIG. 12-c). The pressure manifold is protected by flow restrictors, provided in each of the pressure conduits 522. These flow restrictors limit the mass flow and accordingly the pressure level of the pressure manifold is maintained. In order to protect in a similar way the vacuum level at the vacuum manifold 531, each of the plurality of vacuum suction conduits 532a is equipped with flow restrictors. According to another preferred embodiment of the present invention, a dual sided PP-type (pressure preloaded) non-contact platform is applied for clamping the object to be cleaned. FIG. 12d illustrates a cross sectional view of a typical PP (Pressure-Pressure)-type non-contact platform 503, where most details are similar to FIG. 12-a. Platform 503 is a dual sided platform where the object to be cleaned 100 is clamped without contact from its both sides by two opposing PA-air-cushions (it is also possible to use two opposing PV-type air-cushions, and in that case a PVPV-type air-cushion is defined), having a gap of ε1 (bottom side air-cushion) and ε2 (upper side air-cushion). The dual side PP-type platform has two opposing rigid assemblies 510 and 510a, each having an integral pressure manifold (521, 521a respectively) assembled in a mirror symmetry, and connectors for pressurized air supply (520, 520a respectively).

It should be clear that the description of the embodiments and attached Figures set forth in this specification serves only for a better understanding of the invention, without limiting its scope.

It should also be clear that a person skilled in the art, after reading the present specification could make adjustments or amendments to the embodiments described in the accompanying Figures and the present specification and yet remain within the scope of the present invention.

1. A method for removing contaminants from a surface of an object to be cleaned, the method comprising:
providing a cleaning device fluidically connected to a high-pressure gas supply, the device comprising at least one high-pressure passage of a predetermined miniature lateral scale with a high-pressure outlet for accelerating the gas, the high-pressure outlet characterized by at least one narrow lip, the outlet and the narrow lip defining an active surface;
bringing the active surface of the cleaning device to a predetermined miniature gap from, and substantially parallel to, the surface of the object to be cleaned, thus defining a throat section associated with the device between said at least one narrow lip and the surface of the object to be cleaned, wherein the gap is the width of the throat section;
accelerating the gas to about sonic speeds at the throat section;
thereby producing lateral aeromechanic removal forces that act on the contaminants.

2. The method of claim 1, wherein the width of the throat section is reduced below a predetermined distance to attain a high gradient of velocity of the gas, thereby controlling mass flow.

3. The method of claim 1, wherein the width of the throat section is regulated.

4. The method of claim 1, wherein the width of the throat section is in the order of 100 to 1000 microns.

5. The method of claim 1, wherein the width of the throat section is about 30 to 100 microns.

6. The method of claim 1, wherein the width of the throat section is about 30 microns or less.

7. The method of claim 1, wherein the narrow lip is sharp.

8. The method of claim 1, wherein the lateral scale of the high-pressure passage is about the same in size as the width of the throat section.

9. The method of claim 1, wherein the lateral scale of the high-pressure passage is significantly larger than the width of the throat section.

10. The method of claim 1, wherein the lateral scale of the high-pressure passage is significantly smaller than the width of the throat section.

11. The method of claim 1, wherein pressure of the high-pressure gas supply is regulated.

12. The method of claim 1, wherein pressure of the high-pressure gas supply is up to 5 bars.

13. The method of claim 1, wherein pressure of the high-pressure gas supply is up to 20 bars.

14. The method of claim 1, wherein pressure of the high-pressure gas supply is up to 100 bars.

15. The method of claim 1, further comprising evacuating the gas through at least one gas evacuation passage, confining said at least one high-pressure outlet within, and having external rims, provided in the device.

16. The method of claim 15, wherein evacuating the gas through at least one gas evacuation passage is carried out by vacuum means.

17. The method of claim 16, wherein the vacuum means and the high-pressure gas supply are both regulated to induce substantially zero pressure forces on the object to be cleaned.

18. The method of claim 16, wherein the vacuum means evacuate substantially all the gas so that in effect a dynamically closed environment is formed substantially preventing mass flow of the gas with removed contaminants from escaping to ambient atmosphere.

19. The method of claim 1, further comprising providing a relative motion between the active surface of the device and the surface of the object to be cleaned.

20. The method of claim 19, wherein the relative motion is linear.

21. The method of claim 19, wherein the relative motion is angular.

22. The method of claim 20, wherein the relative motion is combined with linear motion.

23. The method of claim 19, wherein the relative motion is substantially parallel to the surface and the direction of the gas as it accelerates in the throat section.

24. The method of claim 1, wherein the active surface of the device is occasionally relocated from point to point to clean localized portions of the surface to be cleaned.

25. The method of claim 1, wherein the width of the throat section is controlled using physical support.

26. The method of claim 1, wherein the width of the throat section is controlled using non-contact support.

27. The method of claim 26, wherein the non-contact support comprises air-cushioning.

28. The method of claim 1, wherein the gas is air.

29. The method of claim 1, wherein the gas is helium.

30. The method of claim 1, wherein the gas is Nitrogen.

31. The method of claim 1, wherein the gas is heated.

32. The method of claim 1, wherein the surface to be cleaned is heated.

33. The method of claim 1, wherein the gas is excited in high-frequency a periodic fluctuations.

34. The method of claim 33, wherein the gas is excited by piezoelectrically.

35. The method of claim 33, wherein the gas is excited by acoustically.

36. A cleaning device for removing contaminants from a surface of an object to be cleaned, the device adapted to be fluidically connected to a high-pressure gas supply, the device comprising:
at least one high-pressure passage with a predetermined miniature lateral scale with a high-pressure outlet for accelerating the gas, the high-pressure outlet characterized by at least one narrow lip, the outlet and the narrow lip defining an active surface,
whereby when the active surface of the cleaning device is brought to a predetermined miniature gap from, and substantially parallel to, the surface, thus defining a throat section between said at least one narrow lip and the surface of the object to be cleaned, wherein the gap is the width of the throat section, and when the gas is accelerated to about sonic speeds at the throat section, lateral aeromechanic removal forces are produced that act on the contaminants.

37. The device of claim 36, wherein the width of the throat section is controlled by a mechanical means.

38. The device of claim 36, wherein the width of the throat section is controlled by an aeromechanical means.

39. The device of claim 36, wherein the width of the throat section is set to be in the order of 100 to 1000 microns.

40. The device of claim 36, wherein the width of the throat section is set to be about 30 to 100 microns.

41. The device of claim 36, wherein the width of the throat section is set to be about 30 microns or less.

42. The device of claim 36, wherein the narrow lip is sharp.

43. The device of claim 36, wherein the lateral scale of the high-pressure passage is about the same in size as the width of the throat section.

44. The device of claim 36, wherein the lateral scale of the high-pressure passage is significantly larger than the width of the throat section.

45. The device of claim 36, wherein the lateral scale of the high-pressure passage is significantly smaller than the width of the throat section.

46. The device of claim 36, wherein pressure of the high-pressure gas supply is regulated.

47. The device of claim 36, wherein pressure of the high-pressure gas supply is up to 5 bars.

48. The device of claim 36, wherein pressure of the high-pressure gas supply is up to 20 bars.

49. The device of claim 36, wherein pressure of the high-pressure gas supply is up to 100 bars.

50. The device of claim 36, further comprising at least one gas evacuation passage.

51. The device of claim 50, wherein said at least one gas evacuating passage is connected to a vacuum pump.

52. The device of claim 36, further comprising a relative motion means, for providing relative motion between the active surface of the device and the surface to be cleaned.

53. The device of claim 52, wherein the relative motion means provides linear motion.

54. The device of claim 52, wherein the relative motion means provides angular motion.

55. The device of claim 54, wherein the relative motion means facilitates motion combined with linear motion.

56. The device of claim 52, wherein the relative motion is provided by mechanical means.

57. The device of claim 52, wherein the relative motion is provided by aeromechanical means.

58. The device of claim 36, wherein the active surface of the device is adapted to be occasionally relocated from point to point to clean localized portions of the surface to be cleaned.

59. The device of claim 36, wherein the cleaning head unit is supported by mechanical means.

60. The device of claim 36, wherein the cleaning head unit is supported by an air-cushion.

61. The device of claim 36, wherein the object to be cleaned is held with contact by mechanical means.

62. The device of claim 36, wherein the object to be cleaned is supported by non-contact means.

63. The device of claim 62, wherein the non-contact means comprises an air-cushion.

64. The device of claim 36, wherein the cleaning head is integrated in a non-contact supporting platform.

65. The device of claim 36, wherein the high-pressure outlet is elongated.

66. The device of claim 65, wherein said at least one lip comprises at least two elongated lips, whereby two opposing throat sections are defined having substantially equal widths.

67. The device of claim 65, wherein said at least one lip comprises at least two elongated lips, whereby two opposing throat sections are defined having different widths.

68. The device of claim 65, wherein said at least one lip comprises at least two elongated lips, whereby two opposing throat sections are defined, and wherein the passage is substantially perpendicular to the surface of the object to be cleaned.

69. The device of claim 65, wherein said at least one lip comprises at least two elongated lips, whereby two opposing throat sections are defined, and wherein the passage is tilted with respect to the surface of the object to be cleaned.

70. The device of claim 36, wherein the high-pressure outlet is annular.

71. The device of claim 36, wherein the active surface is flat.

72. The device of claim 36, wherein the active surface is arcuate.

73. The device of claim 36, wherein the active surface corresponds in shape to the shape of the surface of the object to be cleaned.

74. The device of claim 36, wherein said at least one high-pressure passage includes a flow restrictor.

75. The device of claim 74, wherein the flow restrictor exhibits self-adaptive return spring properties.

76. The device of claim 75, wherein the flow restrictor is an electromechanical control valve.

77. The device of claim 74, further provided with at least one gas evacuation passage, which includes a flow restrictor.

78. The device of claim 36, comprising at least two high-pressure outlets, the outlets arranged in a substantially parallel orientation.

79. The device of claim 36, comprising at least two high-pressure outlets, the outlets arranged in a substantially orthogonal orientation.

80. The device of claim 3.6, wherein at least one high-pressure outlet is provided that is divided into sectors that can be operated separately.

81. The device of claim 36, comprising at least one high-pressure outlet that can be relocated to a new operational location between two consecutive cleaning sequences.

82. The device of claim 36, comprising at least one high-pressure outlet that is parallel to the object where the object is oriented without any respect to gravity.

83. A cleaning system for removing contaminants from a surface of an object to be cleaned, the system adapted to be fluidically connected to a high-pressure gas supply, the system comprising:
at least one cleaning head comprising at least one high-pressure passage with a predetermined miniature lateral scale with a high-pressure outlet for accelerating the gas, the high-pressure outlet characterized by at least one narrow lip, the outlet and the narrow lip defining an active surface,
supporting means for supporting the object to be cleaned;
relative motion means for providing relative motion between the surface of the object to be cleaned and said at least one cleaning head,
whereby when the active surface of the cleaning device is brought to a predetermined miniature gap from, and substantially parallel to, the surface, thus defining a throat section between said at least one narrow lip and the surface of the object to be cleaned, wherein the gap is the width of the throat section, and when the gas is accelerated to about sonic speeds at the throat section, lateral aeromechanic removal forces are produced that act on the contaminants.

84. The system of claim 83, wherein the system is configured for round objects to be cleaned.

85. The system of claim 83, wherein the system is configured for rectangular objects to be cleaned.

86. The system of claim 83, wherein the supporting means comprises a platform that supports the object, at least partly, without contact by an air-cushion from at least one side.

87. The system of claim 86, wherein the air-cushion is vacuum-preloaded.

88. The system of claim 83, wherein the supporting means comprises a platform that supports the object, at least partly, with contact.

89. The system of claim 83, wherein mechanical means employing friction are used to provide relative motion, by conveying the object.

90. The system of claim 83, wherein mechanical means employing gripping of the object are used to convey the object in order to provide relative motion.

91. The system of claim 83, wherein at least one cleaning head is movable in order to provide the relative motion.

92. The system of claim 83, where said at least one cleaning head and the object to be cleaned are movable in order to provide the relative motion.

93. The system of claim 83, further comprising heating means.

94. The system of claim 93, wherein the heating means comprises a heater for heating the gas.

95. The system of claim 93, wherein the heating means comprises a heater for heating the surface of the object to be cleaned.

96. The system of claim 83, wherein wetting means are provided for wetting the surface to be cleaned, in order to reduce adhesive forces acting on the contaminants.

97. The system of claim 83, wherein an ionizer is provided for ionizing the gas.

98. The system of claim 83, wherein an actuator is provided for exciting the gas to high frequencies periodic fluctuations.

99. The system of claim 83, wherein an optical scanner is provided for inspecting the surface to be cleaned and monitoring removal of contaminants.
